(19) United States
(12) Patent Application Publication
(10) Pub. No.: US 2026/0141955 A1
(43) Pub. Date: May 21, 2026

(54) NON-VOLATILE MEMORY DEVICE AND OPERATING METHOD THEREOF

(71) Applicant: Samsung Electronics Co., Ltd., Suwon-si (KR)

(72) Inventors: Minjie CHOI, Suwon-si (KR); Ji-Sang LEE, Suwon-si (KR); Na-Young CHOI, Suwon-si (KR)

(21) Appl. No.: 19/342,293

(22) Filed: Sep. 26, 2025

(30) Foreign Application Priority Data
Nov. 19, 2024 (KR) 10-2024-0165699

(51) Int. Cl. G11C 16/10; G11C 16/04; G11C 16/24; G11C 16/30

(52) U.S. Cl. CPC G11C 16/10; G11C 16/0483; G11C 16/24; G11C 16/30

(57) ABSTRACT

An example non-volatile memory device includes a control logic circuit configured to generate a program signal, a voltage generator configured generate a first program voltage, a plurality of string select transistors, including first, second, and third string select transistors, a plurality of bit lines, including first, second, and third bit lines respectively connected to the first, second, and third string select transistors, and a page buffer circuit configured to apply a first voltage or a second voltage each bit line. Here, the control logic circuit applies the first voltage to the second bit line and the third bit line, inhibits the second string select transistor by applying the second voltage to the second bit line, and controls the page buffer circuit to inhibit the third string select transistor by applying a third voltage to the third bit line by the second voltage applied to the second bit line.

### CROSS-REFERENCE TO RELATED APPLICATION

This application claims priority to Korean Patent Application No. 10-2024-0165699, filed in the Korean Intellectual Property Office on Nov. 19, 2024, the entire content of which is hereby incorporated by reference.

### BACKGROUND

A vertical NAND (VNAND) artificially forms a threshold voltage of a string select transistor through a program. The narrower the distribution of the threshold voltage of the string select transistor, the more the operating margin of the string select transistor.

In order to narrow the threshold voltage distribution of the string select transistor, the string select transistors that have passed through verify reading are desired to be inhibited. However, unlike memory cells, the string select transistors may not be inhibited through channel boosting, but by the bit line voltage.

In order to smoothly inhibit a string select transistor, a high voltage may be applied to the bit line during a program operation. Research is being conducted on a non-volatile memory device capable of applying a high voltage to the bit line and its operating method.

### SUMMARY

The present disclosure has been proposed to solve the above technical problems, and aspects of implementations of the present disclosure relate to a non-volatile memory device with improved operating margin and an operating method thereof.

The problems to be solved by the present disclosure are not limited to those described above, and other problems not mentioned may be clearly understood by those skilled in the art from the description of the disclosure below.

In some implementations, a non-volatile memory device may include a control logic circuit configured to generate a program signal, a voltage generator configured to receive the program signal from the control logic circuit and generate a first program voltage based on the received program signal, a plurality of string select transistors, including a first string select transistor, a second string select transistor, and a third string select transistor to be programmed based on the first program voltage, a plurality of bit lines, including a first bit line connected to the first string select transistor, a second bit line connected to the second string select transistor, and a third bit line connected to the third string select transistor and adjacent to the second bit line, and a page buffer circuit configured to be connected to the plurality of bit lines and to apply a first voltage or a second voltage greater than the first voltage to each of the plurality of bit lines, in which the control logic circuit applies the first voltage to the second bit line and the third bit line, inhibits the string select transistor by applying the second voltage to the second bit line, and controls the page buffer circuit to inhibit the third string select transistor by applying a third voltage to the third bit line by the second voltage applied to the second bit line.

In some implementations, a non-volatile memory device may include a control logic circuit configured to generate a program signal, a voltage generator configured to receive the program signal from the control logic circuit and generate a first program voltage based on the received program signal, a plurality of string select transistors including a first group of string select transistors, which include at least one first target string select transistor to be programmed by the first program voltage, and a second group of string select transistors, a plurality of bit lines including a first group of bit lines including at least one first target bit line which are connected to the first group of string select transistors and are connected to at least one first target string select transistor, and a second group of bit lines which are disposed between each of the first group of bit lines and are connected to the second group of string select transistors, and a page buffer circuit configured to be connected to the plurality of bit lines and to apply a first voltage or a second voltage greater than the first voltage to each of the plurality of bit lines, in which the control logic circuit inhibits the second group of string select transistors by applying the first voltage to the plurality of bit lines excluding the one or more first target bit lines, and applying the second voltage to the second group of bit lines, and a first group of string select transistors excluding the one or more first target string select transistors are inhibited as a third voltage is applied to a first group of bit lines excluding the one or more first target bit lines by the second voltage applied to the second group of bit lines.

In some implementations, a method of operating a non-volatile memory device including a control logic circuit, a first string select transistor, a second string select transistor, a third string select transistor, a first bit line connected to the first string select transistor, a second bit line connected to the second string select transistor, a third bit line connected to the third string select transistor and adjacent to the second bit line, and a page buffer circuit, may include controlling the page buffer circuit by the control logic circuit to apply a first voltage to the second bit line and the third bit line, controlling the page buffer circuit by the control logic circuit to apply a second voltage greater than the first voltage to the second bit line to inhibit the second string select transistor and the third string select transistor, and programming the first string select transistor by applying a program voltage to a gate electrode of each of the first string select transistor and the third string select transistor by the control logic circuit.

In some implementations, a phenomenon in which a string select transistor is over-programmed may be prevented by applying a voltage higher than an internal power voltage of a page buffer circuit to a bit line connected to a string select transistor that is not to be programmed.

In some implementations, the time required for a program operation may be shortened by performing a two-step process of applying voltage to a bit line connected to a string select transistor not to be programmed and then applying a higher voltage again.

In some implementations, compared to a case where a specific voltage required to inhibit a string select transistor is directly applied, a voltage difference between adjacent program inhibit bit lines is reduced, thereby improving leakage characteristics of the string select transistor and shortening a setup time until a specific voltage required to inhibit a string select transistor is applied to a bit line.

The effects that may be obtained through the present disclosure are not limited to those described above. Any technical effects not mentioned will be clearly understood by those skilled in the art from the description of the disclosure set forth below.

### BRIEF DESCRIPTION OF THE DRAWINGS

The above and other implementations and features of the present disclosure will become more apparent by describing in detail example implementations thereof with reference to the attached drawings.

FIG. 1 is a block diagram illustrating an example of a storage system including a non-volatile memory device.

FIG. 2 is an example block diagram for explaining a storage device illustrated in FIG. 1.

FIG. 3 is an example block diagram for explaining the storage device illustrated in FIG. 2.

FIG. 4 is an example block diagram illustrating the non-volatile memory device of FIG. 1.

FIG. 5 is an example circuit diagram for explaining a memory block of FIG. 4.

FIG. 6 is an example block diagram illustrating a non-volatile memory device.

FIGS. 7 and 8 are example circuit diagrams illustrating a memory cell array and a page buffer.

FIG. 9 is an example circuit diagram illustrating a plurality of bit lines including a first group of bit lines and a second group of bit lines.

FIG. 10 is a diagram illustrating an example of an operating method of a non-volatile memory device.

FIG. 11 is a diagram illustrating an example of an operating method of a non-volatile memory device.

FIGS. 12 and 13 are example diagrams showing a plurality of program voltages applied to a string select transistor.

FIG. 14 is an example timing diagram for explaining the program operation of FIG. 10.

FIG. 15 is an example diagram for explaining the operation of the page buffer circuit at a first time t1 in FIG. 14.

FIG. 16 is an example diagram for explaining the operation of the page buffer circuit at a second time t2 of FIG. 14.

FIG. 17 is an example diagram for explaining the operation of the page buffer circuit at a third time t3 in FIG. 14.

FIG. 18 is an example diagram for explaining the operation of the page buffer circuit at a fourth time t4 in FIG. 14.

FIG. 19 is an example timing diagram for explaining the program operation of FIG. 11.

FIG. 20 is an example diagram for explaining the operation of the page buffer circuit at a sixth time t6 of FIG. 19.

FIG. 21 is an example diagram for explaining the operation of the page buffer circuit at a seventh time t7 of FIG. 19.

FIG. 22 is an example diagram for explaining the operation of the page buffer circuit at an eighth time t8 of FIG. 19.

FIG. 23 is an example block diagram illustrating a system including a non-volatile memory device.

### DETAILED DESCRIPTION

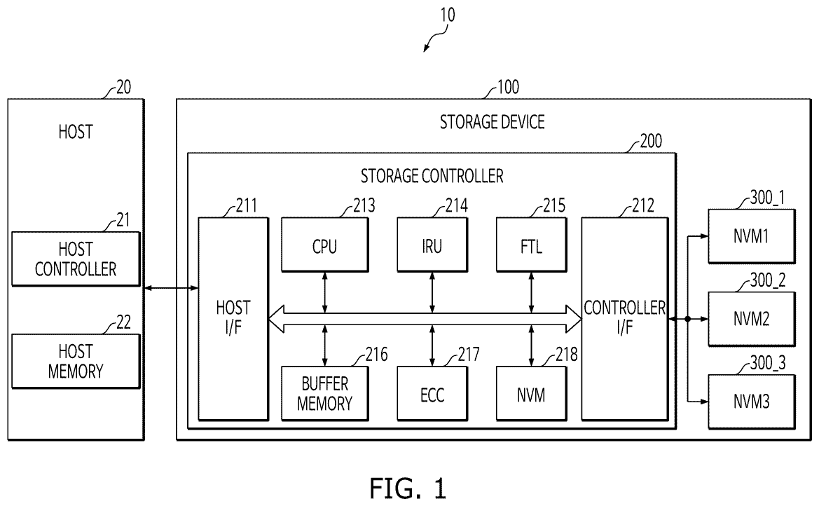

Hereinafter, various implementations of the present disclosure will be described with reference to FIGS. 1 to 23. Throughout the specification, the same reference numerals may refer to the same components.

In the present disclosure, a “target string select transistor” may refer to a string select transistor that is a target of a program in a specific program operation. In the present disclosure, a “target bit line” may refer to a bit line connected to a target string select transistor.

FIG. 1 is a block diagram illustrating an example of a storage system including a non-volatile memory device.

The storage system 10 may include a host 20 and a storage device 100. Additionally, the storage device 100 may include a storage controller 200 and a plurality of non-volatile memory devices (NVMs) 300_1 to 300_3. Additionally, in some implementations, the host 20 may include a host controller 21 and a host memory 22. The host memory 22 may function as a buffer memory for temporarily storing data to be transmitted to the storage device 100 or data transmitted from the storage device 100.

The storage device 100 may include storage media for storing data upon request from the host 20. As an example, the storage device 100 may include at least one of a solid state drive (SSD), an embedded memory, and a removable external memory. If the non-volatile memory device 300_1 to 300_3 is an SSD, the storage device 100 may be a device that follows the non-volatile memory express (NVMe) standard. If the non-volatile memory device 300_1 to 300_3 is an embedded memory or an external memory, the storage device 100 may be a device that follows the universal flash storage (UFS) or embedded multi-media card (eMMC) standard. The host 20 and the storage device 100 may each generate packets according to the adopted standard protocol and transmit the generated packets.

When the non-volatile memory device 300_1 to 300_3 includes a flash memory, the flash memory may include a 2D NAND memory array or a 3D or vertical, or bonding vertical NAND (VNAND) memory array. As another example, the storage device 100 may include various other types of non-volatile memories. For example, the storage device 100 may be applied with various types of memory, such as magnetic RAM (MRAM), spin-transfer torque MRAM, conductive bridging RAM (CBRAM), ferroelectric RAM (FeRAM), phase RAM (PRAM), resistive RAM, and others.

In some implementations, the host controller 21 and host memory 22 may be implemented as separate semiconductor chips. Alternatively, in some implementations, the host controller 21 and the host memory 22 may be integrated into the same semiconductor chip. As an example, the host controller 21 may be one of a number of modules provided in an application processor, and the application processor may be implemented as a system on chip (SoC). Additionally, the host memory 22 may be an embedded memory provided within the application processor, or a non-volatile memory or memory module placed outside the application processor.

The host controller 21 may manage an operation of storing data (e.g., record data) of the host memory 22 in non-volatile memory devices 300_1 to 300_3, or storing data (e.g., read data) of the non-volatile memory devices 300_1 to 300_3 in the host memory 22.

The storage controller 200 may include a host interface 211, a controller interface 212, and a central processing unit (CPU) 213. Additionally, the storage controller 200 may further include an index read unit (IRU) 214, a flash translation layer (FTL) 215, a buffer memory 216, an error correction code (ECC) 217 engine, and an internal non-volatile memory 218. The storage controller 200 may further include a working memory into which a flash translation layer (FTL) 215 is loaded, and data write and read operations for the non-volatile memory may be controlled by the CPU 213 executing the flash translation layer.

The host interface 211 may transmit and receive packets with the host 20. A packet transmitted from the host 20 to the host interface 211 may include a command or data to be written to non-volatile memory devices 300_1 to 300_3, and a packet transmitted from the host interface 211 to the host 20 may include a response to the command or data which is read from the non-volatile memory devices 300_1 to 300_3. The controller interface 212 may transmit data to be written to the non-volatile memory devices 300_1 to 300_3 to the non-volatile memory devices 300_1 to 300_3 or receive data which is read from the non-volatile memory devices 300_1 to 300_3. The controller interface 212 may be implemented to comply with standard protocols such as Toggle or ONFI.

The flash translation layer 215 may perform several functions such as address mapping, wear-leveling, and garbage collection. Additionally, the buffer memory 216 may temporarily store data to be written to the non-volatile memory devices 300_1 to 300_3 or data to be read from the non-volatile memory devices 300_1 to 300_3. The buffer memory 216 may be configured to be provided within the storage controller 200, but may also be disposed outside the storage controller 200.

The ECC engine 217 may perform error detection and correction functions for read data which is read from non-volatile memory devices 300_1 to 300_3. More specifically, the ECC engine 217 may generate parity bits for write data to be written to the non-volatile memory devices 300_1 to 300_3, and the parity bits thus generated may be stored in the non-volatile memory devices 300_1 to 300_3 together with the write data. When reading data from the non-volatile memory devices 300_1 to 300_3, the ECC engine 217 may correct errors in the read data using parity bits which are read from the non-volatile memory devices 300_1 to 300_3 together with the read data, and output error-corrected read data.

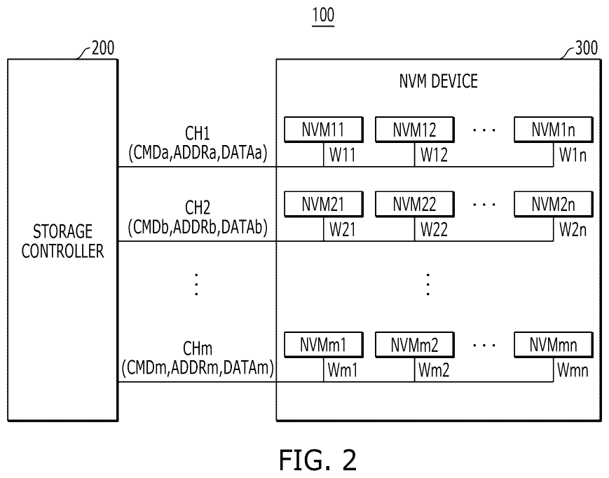

FIG. 2 is an example block diagram for explaining the storage device illustrated in FIG. 1.

Referring to FIG. 2, a non-volatile memory device 300 and a storage controller 200 may be connected through a plurality of channels CH1 to CHm.

The non-volatile memory device 300 may include a plurality of non-volatile memory devices NVM11 to NVMmn. A plurality of non-volatile memory devices NVM11 to NVMmn may correspond to the non-volatile memory devices 300_1 to 300_3 of FIG. 1. Each of the non-volatile memory devices NVM11 to NVMmn may be connected to one of the plurality of channels CH1 to CHm through a corresponding way. In some implementations, each of the non-volatile memory devices NVM11 to NVMmn may be implemented as any memory unit that may operate according to individual commands from the storage controller 200. For example, each of the non-volatile memory devices NVM11 to NVMmn may be implemented as a chip or a die, but the present disclosure is not limited thereto.

The storage controller 200 may transmit and receive signals with a non-volatile memory device 300 through a plurality of channels CH1 to CHm. For example, the storage controller 200 may transmit commands CMDa to CMDm, addresses ADDRa to ADDRm, and data DATAa to DATAm to the non-volatile memory device 300 through channels CH1 to CHm, or receive data DATAa to DATAm from the non-volatile memory device 300.

The storage controller 200 may select one of the non-volatile memory devices connected to each channel through each channel and transmit and receive signals with the selected non-volatile memory device.

The storage controller 200 may transmit and receive signals in parallel with a non-volatile memory device 300 through different channels. For example, the storage controller 200 may transmit a command CMDb to the memory device NVM21 through the second channel CH2 while transmitting a command CMDa to the memory device NVM11 through the first channel CH1. For example, the storage controller 200 may receive data DATAb from the memory device NVM21 through the second channel CH2 while receiving data DATAa from the memory device NVM11 through the first channel CH1.

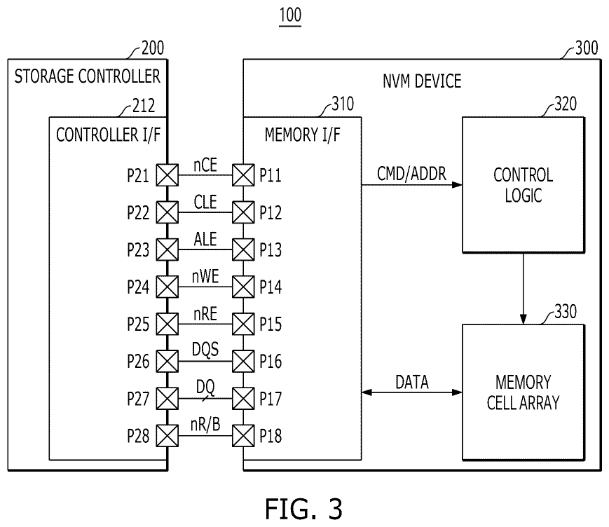

FIG. 3 is an example block diagram for explaining the storage device illustrated in FIG. 2.

Referring to FIG. 3, the storage device 100 may include a storage controller 200 and a non-volatile memory device 300. The non-volatile memory device 300 may correspond to one of the non-volatile memory devices NVM11 to NVMmn according to some implementations that communicate with the storage controller 200 of FIG. 2 based on one of the plurality of channels CH1 to CHm of FIG. 2.

A non-volatile memory device 300 may include first to eighth pins P11 to P18, a memory interface circuit 310, a control logic circuit 320, and a memory cell array 330.

The memory interface circuit 310 may receive a chip enable signal (nCE) from the storage controller 200 through the first pin P11. The memory interface circuit 310 may transmit and receive signals with the storage controller 200 through the second to eighth pins P12 to P18 according to the chip enable signal (nCE). For example, when the chip enable signal (nCE) is in an enabled state (e.g., high level), the memory interface circuit 310 may transmit and receive signals with the storage controller 200 through the second to eighth pins P12 to P18.

The memory interface circuit 310 may receive a command latch enable signal (CLE), an address latch enable signal (ALE), and a write enable signal (nWE) from the storage controller 200 through the second to fourth pins P12 to P14. The memory interface circuit 310 may receive a data signal DQ from the storage controller 200 or transmit a data signal DQ to the storage controller 200 through the seventh pin P17. Commands CMD, addresses ADDR, and data DATA may be transmitted through data signals DQ. For example, a data signal DQ may be transmitted over a plurality of data signal lines. In this case, the seventh pin P17 may include a plurality of pins corresponding to a plurality of data signals.

The memory interface circuit 310 may obtain a command CMD from a data signal DQ received in an enable section (e.g., a high level state) of a command latch enable signal CLE based on the toggle timings of a write enable signal nWE. The memory interface circuit 310 may obtain an address ADDR from a data signal DQ received in an enable section (e.g., high level state) of an address latch enable signal ALE based on the toggle timings of a write enable signal nWE.

In some implementations, the write enable signal nWE may remain in a static state (e.g., a high level or a low level) and toggle between the high level and the low level. For example, the write enable signal nWE may be toggled during a section where a command CMD or an address ADDR is transmitted. Accordingly, the memory interface circuit 310 may obtain a command CMD or an address ADDR based on the toggle timings of the write enable signal nWE.

The memory interface circuit 310 may receive a read enable signal nRE from the storage controller 200 through the fifth pin P15. The memory interface circuit 310 may receive a data strobe signal DQS from the storage controller 200 through the sixth pin P16, or transmit a data strobe signal DQS to the storage controller 200.

In a data DATA output operation of the non-volatile memory device 300, the memory interface circuit 310 may receive a read enable signal nRE that toggles through the fifth pin P15 before outputting data DATA. The memory interface circuit 310 may generate a data strobe signal DQS that toggles based on the toggling of the read enable signal nRE. For example, the memory interface circuit 310 may generate a data strobe signal DQS that begins to toggle after a predetermined delay (e.g., tDQSRE) based on the toggling start time of the read enable signal nRE. The memory interface circuit 310 may transmit a data signal DQ including data DATA based on the toggle timing of a data strobe signal DQS. Accordingly, data DATA may be aligned in the toggle timing of the data strobe signal DQS and transmitted to the storage controller 200.

In a data DATA input operation of a non-volatile memory device 300, when a data signal DQ including data DATA is received from a storage controller 200, the memory interface circuit 310 may receive a data strobe signal DQS that toggles together with the data DATA from the storage controller 200. The memory interface circuit 310 may obtain data DATA from the data signal DQ based on the toggle timing of the data strobe signal DQS. For example, the memory interface circuit 310 may obtain data DATA by sampling the data signal DQ at the rising edge and falling edge of the data strobe signal DQS.

The memory interface circuit 310 may transmit a ready/busy output signal nR/B to the storage controller 200 through the 8th pin P18. The memory interface circuit 310 may transmit status information of the non-volatile memory device 300 to the storage controller 200 through a ready/busy output signal nR/B. When the non-volatile memory device 300 is in a busy state (i.e., when internal operations of the non-volatile memory device 300 are being performed), the memory interface circuit 310 may transmit a ready/busy output signal nR/B indicating the busy state to the storage controller 200. When the non-volatile memory device 300 is in a ready state (i.e., when internal operations of the non-volatile memory device 300 are not performed or completed), the memory interface circuit 310 may transmit a ready/busy output signal nR/B indicating the ready state to the storage controller 200. For example, while a non-volatile memory device 300 reads data DATA from a memory cell array 330 in response to a page read command, a memory interface circuit 310 may transmit a ready/busy output signal nR/B indicating a busy state (e.g., low level) to the storage controller 200. For example, while the non-volatile memory device 300 programs data DATA into the memory cell array 330 in response to a program command, the memory interface circuit 310 may transmit a ready/busy output signal nR/B indicating a busy state to the storage controller 200.

The control logic circuit 320 may control various operations of the non-volatile memory device 300. The control logic circuit 320 may receive a command/address CMD/ADDR obtained from the memory interface circuit 310. The control logic circuit 320 may generate control signals for controlling other components of the non-volatile memory device 300 according to the received command/address CMD/ADDR. For example, the control logic circuit 320 may generate various control signals for programming data DATA into the memory cell array 330 or reading data DATA from the memory cell array 330. Alternatively, control signals may be generated to adjust channel potentials within the memory cell array.

The memory cell array 330 may store data DATA obtained from the memory interface circuit 310 under the control of the control logic circuit 320. The memory cell array 330 may output stored data DATA to the memory interface circuit 310 under the control of the control logic circuit 320. Additionally, the channel potential within the memory cell array 330 may be adjusted according to the control of the control logic circuit 320.

The memory cell array 330 may include a plurality of memory cells. For example, the plurality of memory cells may be flash memory cells. However, the present disclosure is not limited thereto, and the memory cells may be resistive random access memory (RRAM) cells, ferroelectric random access memory (FRAM) cells, phase change random access memory (PRAM) cells, thyristor random access memory (TRAM) cells, and magnetic random access memory (MRAM) cells. Hereinafter, implementations will be described focusing on an implementation in which the memory cells are NAND flash memory cells.

The storage controller 200 may include first to eighth pins P21 to P28 and a controller interface 212. The first to eighth pins P21 to P28 may correspond to the first to eighth pins P11 to P18 of the non-volatile memory device 300.

The controller interface 212 may transmit a chip enable signal nCE to the non-volatile memory device 300 through the first pin P21. The controller interface 212 may transmit and receive signals to and from a selected non-volatile memory device 300 through the chip enable signal nCE and the second to eighth pins P22 to P28.

The controller interface 212 may transmit a command latch enable signal CLE, an address latch enable signal ALE, and a write enable signal nWE to the non-volatile memory device 300 through the second to fourth pins P22 to P24. The controller interface 212 may transmit a data signal DQ to the non-volatile memory device 300 or receive a data signal DQ from the non-volatile memory device 300 via the seventh pin P27.

The controller interface 212 may transmit a data signal DQ including a command CMD or an address ADDR together with a toggling write enable signal nWE to the non-volatile memory device 300. The controller interface 212 may transmit a data signal DQ including a command CMD to the non-volatile memory device 300 by transmitting a command latch enable signal CLE having an enable state, and may transmit a data signal DQ including an address ADDR to the non-volatile memory device 300 by transmitting an address latch enable signal ALE having an enable state.

The controller interface 212 may transmit a read enable signal nRE to the non-volatile memory device 300 via the fifth pin P25. The controller interface 212 may receive a data strobe signal DQS from the non-volatile memory device 300 or transmit a data strobe signal DQS to the non-volatile memory device 300 via the sixth pin P26.

In a data DATA output operation of the non-volatile memory device 300, the controller interface 212 may generate a toggling read enable signal nRE and transmit the read enable signal nRE to the non-volatile memory device 300. For example, the controller interface 212 may generate a read enable signal nRE that changes from a fixed state (e.g., a high level or a low level) to a toggle state before data DATA is output. Accordingly, a data strobe signal DQS that toggles based on a read enable signal nRE in the non-volatile memory device 300 may be generated. The controller interface 212 may receive a data signal DQ including data DATA together with a toggling data strobe signal DQS from the non-volatile memory device 300. The controller interface 212 may obtain data DATA from the data signal DQ based on the toggle timing of the data strobe signal DQS.

In a data input operation of a non-volatile memory device 300, the controller interface 212 may generate a toggling data strobe signal DQS. For example, the controller interface 212 may generate a data strobe signal DQS that changes from a fixed state (e.g., a high level or a low level) to a toggle state before transmitting data DATA. The controller interface 212 may transmit a data signal DQ containing data DATA to the non-volatile memory device 300 based on the toggle timings of a data strobe signal DQS.

The controller interface 212 may receive a ready/busy output signal nR/B from the non-volatile memory device 300 through the eighth pin P28. The controller interface 212 may determine status information of the non-volatile memory device 300 based on the ready/busy output signal nR/B.

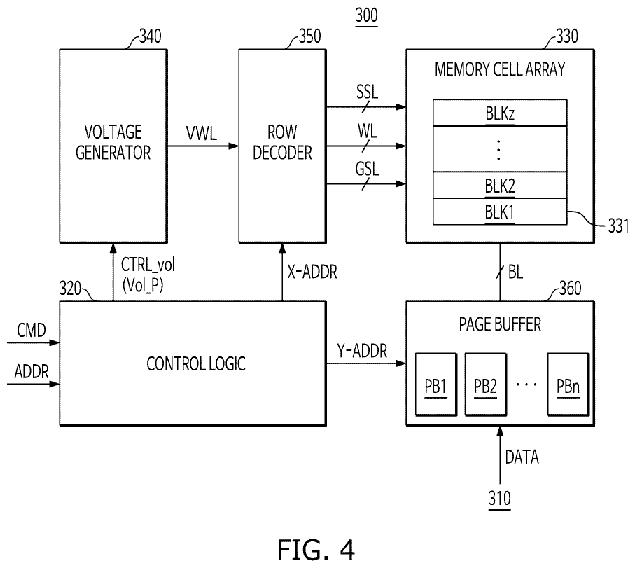

FIG. 4 is an example block diagram illustrating the non-volatile memory device of FIG. 1.

Referring to FIG. 4, a non-volatile memory device 300 may include a control logic circuit 320, a memory cell array 330, a page buffer circuit 360, a voltage generator 340, and a row decoder 350. The non-volatile memory device 300 may further include a memory interface circuit 310 of FIG. 3, and may further include column logic, a pre-decoder, a temperature sensor, a command decoder, an address decoder, etc.

The control logic circuit 320 may control various operations within the non-volatile memory device 300. The control logic circuit 320 may output various control signals in response to a command CMD and/or address ADDR from the memory interface circuit 310. For example, the control logic circuit 320 may output a voltage control signal CTRL_vol, a row address X-ADDR, and a column address Y-ADDR. The voltage control signal CTRL_vol may include a program signal or an erase signal.

The memory cell array 330 may include a plurality of memory blocks BLK1 to BLKz (z is a positive integer), and each of the plurality of memory blocks BLK1 to BLKz may include a plurality of memory cells. The memory cell array 330 may be connected to a page buffer circuit 360 through bit lines BL and may be connected to a row decoder 350 through word lines WL, string select lines SSL and ground select lines GSL.

In some implementations, the memory cell array 330 may include a three-dimensional memory cell array, and the three-dimensional memory cell array may include a plurality of NAND strings. Each NAND string may include memory cells each connected to word lines stacked vertically on the substrate. In some implementations, the memory cell array 330 may include a two-dimensional memory cell array, and the two-dimensional memory cell array may include a plurality of NAND strings arranged along the row and column directions.

The page buffer circuit 360 may include a plurality of page buffers PB1 to PBn (n is an integer greater than or equal to 3), and the plurality of page buffers PB1 to PBn may be respectively connected to memory cells through a plurality of bit lines BL. The page buffer circuit 360 may select at least one bit line among the bit lines BL in response to a column address Y-ADDR. The page buffer circuit 360 may operate as a write driver or a sense amplifier depending on the operating mode. For example, during a program operation, the page buffer circuit 360 may apply a bit line voltage corresponding to data to be programmed to a selected bit line. During a read operation, the page buffer circuit 360 may detect data stored in a memory cell by detecting the current or voltage of the selected bit line.

The voltage generator 340 may generate various types of voltages for performing program, read, and erase operations based on a voltage control signal CTRL_vol. For example, the voltage generator 340 may generate a program voltage, a read voltage, a program verify voltage, an erase voltage, etc. as a word line voltage VWL.

A row decoder 350 may select one of a plurality of word lines WL and one of a plurality of string select lines SSL in response to a row address X-ADDR. For example, during a program operation, the row decoder 350 may apply a program voltage and a program verification voltage to a selected word line, and during a read operation, the row decoder 350 may apply a read voltage to the selected word line.

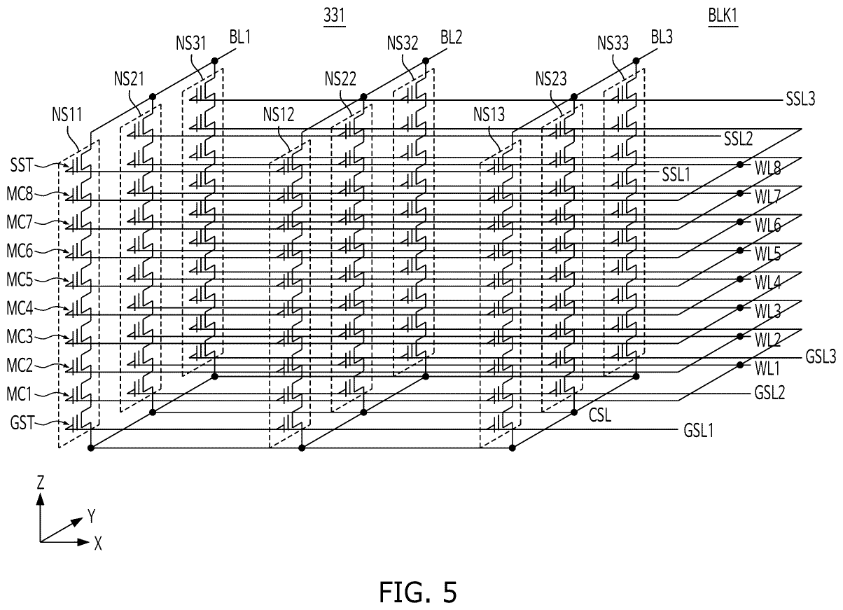

FIG. 5 is an example circuit diagram for explaining the memory block of FIG. 4.

Referring to FIG. 5, cell strings NS11 to NS33 may be disposed between bit lines BL1 to BL3 and a common source line CSL. Each cell string (e.g., NS11) may include a ground select transistor GST, a plurality of memory cells MC1 to MC8, and a string select transistor SST.

The string select transistor SST may be connected to a string select line SSL. The string select line SSL may be separated into first to third string select lines SSL1 to SSL3. A ground select transistor GST may be connected to the ground select lines GSL1 to GSL3. In some implementations, the ground select lines GSL1 to GSL3 may be connected to each other. A string select transistor SST may be connected to a bit line BL, and a ground select transistor GST may be connected to a common source line CSL.

A plurality of memory cells MC1 to MC8 may each be connected to a corresponding word line WL1 to WL8. A set of memory cells that are connected to a single word line and programmed simultaneously may be called a page. A memory block BLK1 may contain a plurality of pages as illustrated. Additionally, a plurality of pages may be accessed in one word line.

These pages may be the units of data programs and reads, and the memory blocks BLK1 may be the units of data erasure. That is, when a non-volatile memory device performs a program or read operation, data may be programmed or read in units of pages, and when the non-volatile memory device performs an erase operation, data may be erased in units of memory blocks. That is, data stored in all memory cells MC1 to MC8 included in one memory block may be erased at once.

Meanwhile, each memory cell MC1 to MC8 may store one bit of data or two or more bits of data. One memory cell MC1 to MC8 may be, for example, a single-level cell (SLC) memory in which one bit of data is written to one memory cell, or a multi-level cell (MLC) memory that stores two or more bits of data. A multi-level cell may be, for example, a triple level cell TLC in which three bits of data are written to one memory cell, or a quadruple level cell QLC in which four bits of data are written.

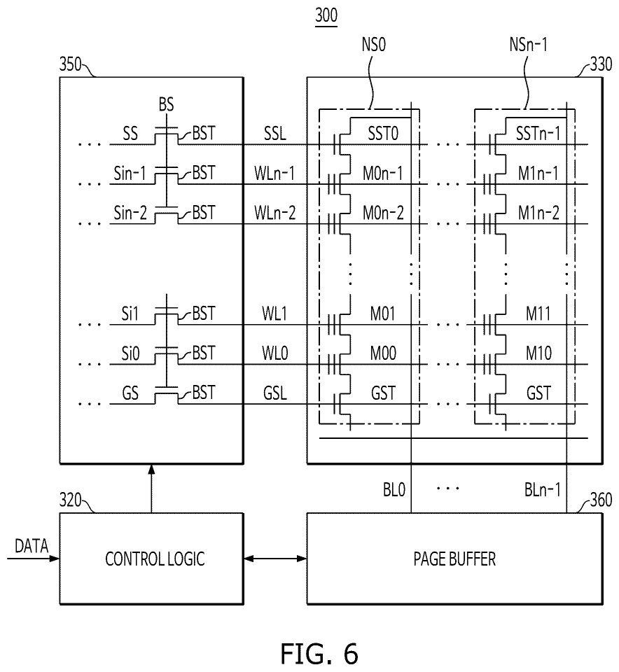

FIG. 6 is an example block diagram illustrating a non-volatile memory device.

Referring to FIG. 6, a non-volatile memory device 300 may include a control logic circuit 320, a row decoder 350, a memory cell array 330, and a page buffer circuit 360. The rows of the memory cell array 330 may be driven by a row decoder 350, and the columns may be driven by a page buffer circuit 360. The row decoder 350 and the page buffer circuit 360 may be driven by the control logic circuit 320.

The memory cell array 330 may be composed of a plurality of memory cells M00 to M1n-1. Memory cell blocks are not limited to two dimensions and may also be stacked in three dimensions. Each memory cell block may include a plurality of memory cell strings NS0 to NSn-1. Each of the cell strings NS0 to NSn-1 may include a plurality of memory cells M00 to M1n-1 per string. Channels of memory cells M00 to M1n-1 of cell strings NS0 to NSn-1 may be connected in series between channels of a plurality of string select transistors (SST) SST0 to SSTn-1 and the channel of the ground select transistor.

Each block of the memory cell array 330 may include a string select line SSL, a ground select line GSL, a plurality of word lines WL0 to WLn-1, and a plurality of bit lines BL0 to BLn-1. The string select line may be commonly connected to the gates of a plurality of string select transistors SST0 to SSTn-1. Each of the plurality of word lines WL0 to WLn-1 may be commonly connected to the control gates of a plurality of corresponding memory cells M00 to M1n-1. A ground select line GSL may be commonly connected to the gates of a plurality of ground select transistors GSTs. And the ground select line GSL, a plurality of word lines WL0 to WLn-1, and string select line SSL may each receive corresponding select signals GS, Si0 to Sin-1 and SS through corresponding block select transistors BST. Block select transistors BSTs may be included in the row decoder 350 and may be connected to be commonly controlled by a block control signal BS.

The row decoder 350 may select one word line among a plurality of word lines WL0 to WLn-1 according to row address information. The row decoder 350 may supply word line voltages according to each operation mode to selected word lines and unselected word lines. For example, the row decoder 350 may supply a program voltage to the selected word lines and a pass voltage to the unselected word lines in the program operation mode. Additionally, the row decoder 350 may supply a ground voltage GND to the selected word line and supply a read voltage to the unselected word lines in the read operation mode. For this purpose, the row decoder 350 may receive selection signals Si0 to Sin-1 from the word line driver. Additionally, the row decoder 350 may provide word line voltages to word lines WL0 to WLn-1 corresponding to the input select signals Si0 to Sin-1. The select signals Si0 to Sin-1 may have voltage levels corresponding to at least one of the program voltage, the pass voltage, and the read voltage. And the word line voltage may be provided to word lines WL0 to WLn-1 corresponding to the corresponding select signals Si0 to Sin-1.

A plurality of bit lines BL0 to BLn-1 arranged on the memory cell array 330 may be connected to a page buffer circuit 360. The page buffer circuit 360 may provide page buffer data corresponding to each of a plurality of bit lines BL0 to BLn-1. Each page buffer may be implemented to share a pair of bit lines. The page buffer circuit 360 may supply power voltage or ground voltage to a plurality of bit lines BL0 to BLn-1 depending on the data to be programmed in the program operation mode. And the page buffer circuit 360 may detect data from selected memory cells through a plurality of bit lines BL0 to BLn-1 in read/verify operation mode. The detection operation of the page buffer circuit 360 may determine whether a memory cell is a programmed cell or an erased cell.

By controlling the row decoder 350 and/or the page buffer circuit 360 through the control logic circuit 320, the word lines WL0 to WLn-1 and/or bit lines BL0 to BLn-1 connected to the memory cell array 330 may be operated. The control logic circuit 320 may receive data from the storage controller 200 of FIG. 1, but the implementation is not limited to this example.

In some implementations, the memory cell array 330 may be implemented as a two-dimensional structure or a three-dimensional structure. An implementation in which a memory cell array 330 is implemented three-dimensionally will be described below.

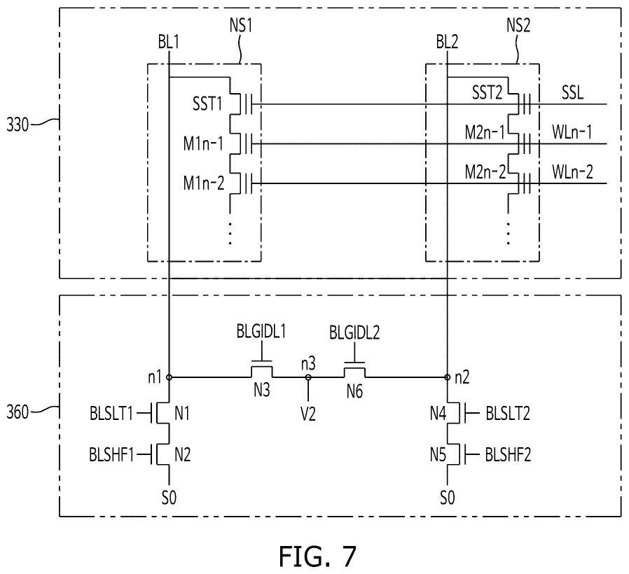

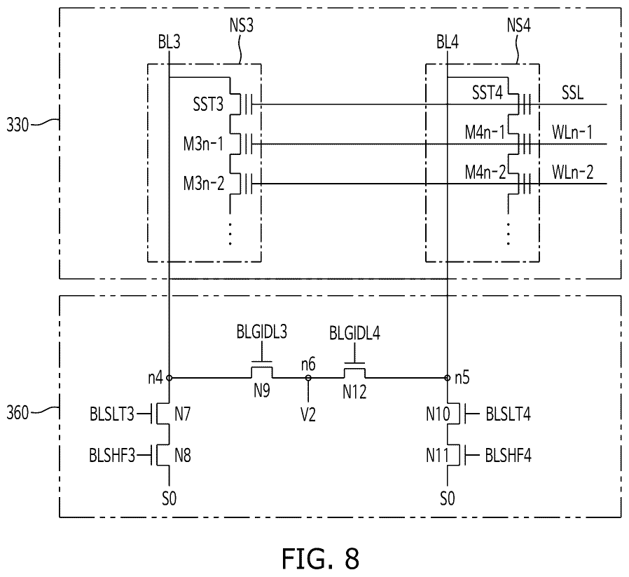

FIGS. 7 and 8 are example circuit diagrams illustrating a memory cell array and a page buffer.

Referring to FIGS. 7 and 8, a memory cell array 330 may include bit lines BL1, BL2, BL3 and BL4, string select transistors SST1, SST2, SST3 and SST4, and memory cells M1n-1, M1n-2, M2n-1, M2n-2, M3n-1, M3n-2, M4n-1 and M4n-2. Although the drawings show only some of the plurality of bit lines, some of the plurality of string select transistors, and some of the plurality of memory cells, the number of bit lines, the number of string select transistors, and the number of memory cells may be greater than those shown in the drawings.

A first cell string NS1 may include a first bit line BL1, a string select transistor SST1, and memory cells M1n-1 and M1n-2. The second cell string NS2 may include a second bit line BL2, a string select transistor SST2, and memory cells M2n-1 and M2n-2. A third cell string NS3 may include a third bit line BL3, a string select transistor SST3, and memory cells M3n-1 and M3n-2. A fourth cell string NS4 may include a fourth bit line BL4, a string select transistor SST4, and memory cells M4n-1 and M4n-2.

The gate electrodes of the string select transistors SST1, SST2, SST3 and SST4 may be commonly connected to a string select line SSL. The gate electrodes of the memory cells M1n-1, M2n-1, M3n-1 and M4n-1 may be commonly connected to the word line WLn-1. The gate electrodes of the memory cells M1n-2, M2n-2, M3n-2 and M4n-2 may be commonly connected to the word line WLn-2.

The page buffer circuit 360 may include bit line select transistors N1, N4, N7 and N10, bit line shut-off transistors N2, N5, N8, N11, and precharge transistors N3, N6, N9 and N12.

The internal power voltage or ground voltage of the page buffer circuit 360 may be applied to the node SO of the page buffer circuit 360.

Referring to FIG. 7, one end of the first bit line select transistor N1 may be connected to the first node n1. The first node n1 may be connected to one end of a string select transistor SST1. The other end of the first bit line select transistor N1 may be connected to one end of the first bit line shut-off transistor N2. The other end of the first bit line shut-off transistor N2 may be connected to the node SO.

One end of the first precharge transistor N3 may be connected to the first node n1. The other end of the first precharge transistor N3 may be connected to the third node n3. One end of the second precharge transistor N6 may be connected to the third node n3. A voltage V2 may be applied to the third node n3. In some implementations, the voltage V2 may be generated from a voltage generator (340 of FIG. 4) and provided to a third node n3.

The other end of the second precharge transistor N6 may be connected to the second node n2. One end of the second bit line select transistor N4 may be connected to the second node n2. The second node n2 may be connected to one end of a string select transistor SST2. The other end of the second bit line select transistor N4 may be connected to one end of the second bit line shut-off transistor N5. The other end of the second bit line shut-off transistor N5 may be connected to the node SO.

Referring to FIG. 8, one end of the third bit line select transistor N7 may be connected to the fourth node n4. The fourth node n4 may be connected to one end of a string select transistor SST3. The other end of the third bit line select transistor N7 may be connected to one end of the third bit line shut-off transistor N8. The other end of the third bit line shut-off transistor N8 may be connected to the node SO.

One end of the third precharge transistor N9 may be connected to the fourth node n4. The other end of the third precharge transistor N9 may be connected to the sixth node n6. One end of the fourth precharge transistor N12 may be connected to the sixth node n6. A voltage V2 may be applied to the sixth node n6. In some implementations, the voltage V2 may be generated from a voltage generator (340 of FIG. 4) and provided to the sixth node n6.

The other end of the fourth precharge transistor N12 may be connected to the fifth node n5. One end of the fourth bit line select transistor N10 may be connected to the fifth node n5. The fifth node n5 may be connected to one end of a string select transistor SST4. The other end of the fourth bit line select transistor N10 may be connected to one end of the fourth bit line shut-off transistor N11. The other end of the fourth bit line shut-off transistor N11 may be connected to the node SO.

Referring to FIGS. 7 and 8, bit line select signals BLSLT1, BLSLT2, BLSLT3 and BLSLT4 controlling bit line select transistors N1, N4, N7 and N10, bit line shut-off signals BLSHF1, BLSHF2, BLSHF3 and BLSHF4 controlling bit line shut-off transistors N2, N5, N8 and N11, and precharge signals BLGIDL1, BLGIDL2, BLGIDL3 and BLGIDL4 controlling precharge transistors N3, N6, N9 and N12 may be generated in a control logic circuit (e.g., 320 of FIG. 6), but the implementations are not limited to these examples.

Each of the bit line select transistors N1, N4, N7 and N10 may operate depending on whether each of the bit line select signals BLSLT1, BLSLT2, BLSLT3 and BLSLT4 is applied. For example, each of the bit line select transistors N1, N4, N7 and N10 may be turned on or off depending on whether each of the bit line select signals BLSLT1, BLSLT2, BLSLT3 and BLSLT4 is applied, thereby applying or blocking the voltage of the node SO to each of the bit lines BL1, BL2, BL3 and BL4.

Each of the bit line shut-off transistors N2, N5, N8 and N11 may operate depending on whether each of the bit line shut-off signals BLSHF1, BLSHF2, BLSHF3 and BLSHF4 is applied and/or the applied voltage intensity. For example, each of the bit line shut-off transistors N2, N5, N8 and N11 may be turned on or off depending on whether each of the bit line shut-off signals BLSHF1, BLSHF2, BLSHF3 and BLSHF4 is applied and/or the applied voltage intensity, thereby applying or blocking the voltage of the node SO to each of the bit lines BL1, BL2, BL3 and BL4. A part of the page buffer circuit 360 including each of the bit line shut-off transistors N2, N5, N8 and N11 may be referred to as a “bit line shut-off circuit” or a “shut-off circuit”.

Each of the precharge transistors N3, N6, N9 and N12 may operate depending on whether each of the precharge signals BLGIDL1, BLGIDL2, BLGIDL3 and BLGIDL4 is applied and/or the applied voltage intensity. For example, each of the precharge transistors N3, N6, N9 and N12 may be turned on or off depending on whether each of the precharge signals BLGIDL1, BLGIDL2, BLGIDL3 and BLGIDL4 is applied and/or the applied voltage intensity, thereby applying or blocking the voltage V2 of the third node n3 and/or the sixth node n6 to each of the bit lines BL1, BL2, BL3 and BL4. A part of the page buffer circuit 360 including each of the precharge transistors N3, N6, N9 and N12 may be referred to as a “precharge circuit”.

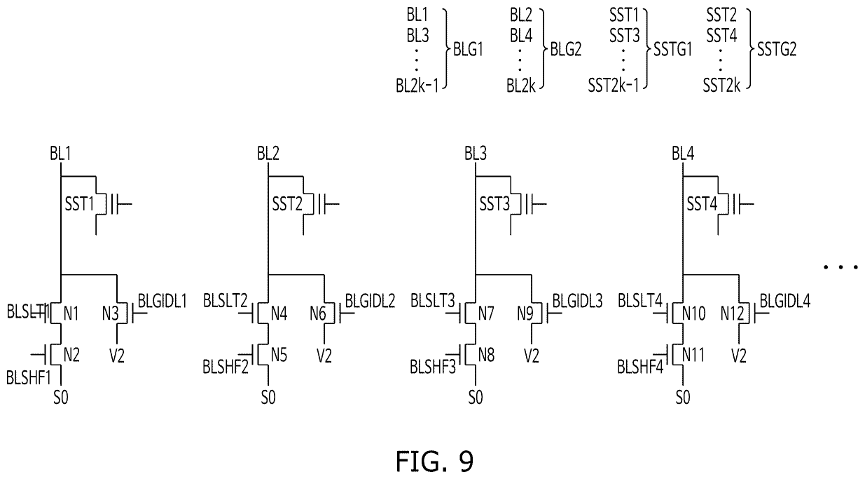

FIG. 9 is an example circuit diagram illustrating a plurality of bit lines including a first group of bit lines BLG1 and a second group of bit lines BLG2. The bit lines BL1 to BL4 illustrated in FIG. 9 may be disposed in a form in which the bit lines BL1 to BL4 described above with reference to FIGS. 7 and 8 are disposed.

The bit lines of the first group BLG1 may include odd-numbered bit lines among the bit lines BL1 to BL2k. For example, the bit line BLG1 of the first group may include the first bit line BL1 to the (2k-1)-th bit line BL2k-1 (k is a natural number greater than or equal to 2). Alternatively, the bit lines BLG1 of the first group may include even-numbered bit lines among the bit lines BL1 to BL2k.

The second group of bit lines BLG2 may include even-numbered bit lines among the bit lines BL1 to BL2k. For example, the second group of bit lines BLG2 may include the second bit line BL2 to the 2k-th bit line BL2k. Alternatively, the second group of bit lines BLG2 may include odd-numbered bit lines among the bit lines BL1 to BL2k.

Each of the bit lines BLG2 of the second group may be arranged between each of the bit lines BLG1 of the first group. Each bit line BLG1 of the first group may be arranged between each bit line BLG2 of the second group. The bit lines BLG1 of the first group are not adjacent to each other, the bit lines BLG2 of the second group are not adjacent to each other, and each of the bit lines BLG1 of the first group and each of the bit lines BLG2 of the second group may be arranged to intersect each other.

The string select transistors SSTG1 of the first group may include a string select transistor connected to the bit line BLG1 of the first group. For example, the string select transistors SSTG1 of the first group may include the first string select transistor SST1 to the (2k-1)-th string select transistor SST2k-1 among the string select transistors SST1 to SST2k.

The string select transistors SSTG2 of the second group may include a string select transistor connected to the bit line BLG2 of the second group. For example, the string select transistors SSTG2 of the second group may include the second string select transistor SST2 to the 2k-th string selection transistor SST2k among the string select transistors SST1 to SST2k.

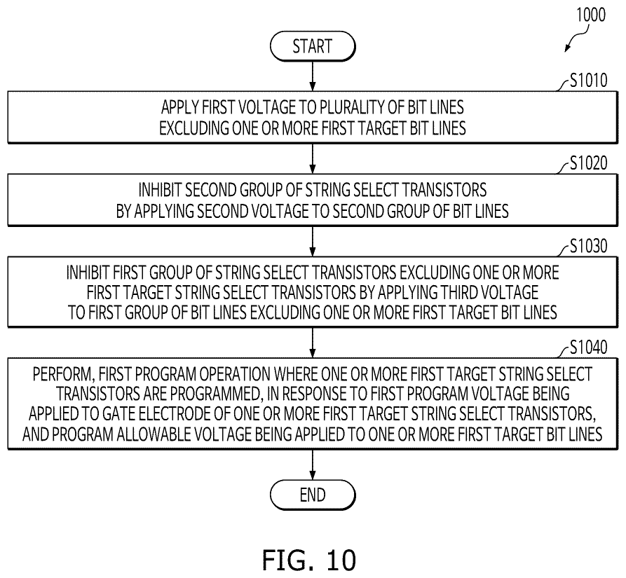

FIG. 10 is a diagram illustrating an example of an operating method 1000 of a non-volatile memory device. The method 1000 illustrated in FIG. 10 may be performed by a control logic circuit (e.g., 320 of FIG. 4) and a page buffer circuit (e.g., 360 of FIG. 4) of a non-volatile memory device.

Referring to FIGS. 9 and 10 together, the control logic circuit may apply a first voltage to a plurality of bit lines BL1 to BL2k excluding one or more first target bit lines by controlling the page buffer circuit (S1010). For example, the control logic circuit may apply a first voltage to a first group of bit lines BLG1, excluding one or more of the first target bit lines, and a second group of bit lines BLG2. The first voltage may be an internal power voltage of the page buffer circuit.

The one or more first target bit lines of step S1010 may be bit lines connected to one or more first target string select transistors, and the one or more first target string select transistors may be string select transistors to be programmed by a first program voltage in a first program operation among incremental step pulse program (ISPP) operations including a plurality of program operations. The one or more first target string select transistors may be any string select transistor included in the first group of string select transistors SSTG1. The first program voltage may be a program voltage generated by a voltage generator (e.g., 340 of FIG. 4) based on a generated program signal after the control logic circuit generates a program signal based on a control signal associated with the first program operation or ISPP operation.

The control logic circuit may inhibit the string select transistor SSTG2 of the second group by applying a second voltage to the bit lines BLG2 of the second group by controlling the page buffer circuit (S1020). For example, the control logic circuit may shut off the first voltage applied to the second group of bit lines BLG2 at step S1010 by controlling the page buffer circuit, and then apply the second voltage. Shutting off of the first voltage applied to the bit line BLG2 of the second group and applying the second voltage may be performed substantially simultaneously.

Because the string select transistor SSTG2 of the second group is inhibited at step S1020, even if the first program voltage is applied to the gate electrode of the string select transistor SSTG2 of the second group, the string select transistor SSTG2 of the second group may be program-inhibited.

At step S1020, a third voltage is applied to the bit lines BLG1 of the first group, excluding one or more first target bit lines, by the second voltage applied to the bit lines BLG2 of the second group, so that the string select transistors SSTG1 of the first group, excluding one or more first target string select transistors, may be inhibited (S1030). For example, because each of the bit lines BLG1 of the first group is coupled to each of the bit lines BLG2 of the second group to which the second voltage V2 is applied, even if the control logic circuit does not control the page buffer circuit to apply a separate voltage, a third voltage (e.g., 2.28 to 2.38 V) may be applied to the bit lines BLG1 of the first group except for one or more of the first target bit lines. At this time, the third voltage may be higher than the first voltage of step S1010 and lower than the second voltage of step S1010. The implementation is not limited to this example, and the same voltage is not necessarily applied to each of the bit lines BLG1 of the first group excluding one or more of the first target bit lines, and voltages of different magnitudes may be applied to each of the bit lines BLG1 of the first group excluding one or more of the first target bit lines depending on various factors such as interference.

By inhibiting the string select transistors SSTG1 of the first group excluding one or more of the first target string select transistors, even if the first program voltage is applied to the gate electrodes of the string select transistors SSTG1 of the first group excluding one or more of the first target string select transistors, the string select transistors SSTG1 of the first group excluding one or more of the first target string select transistors may be program-inhibited.

The control logic circuit may apply a program allowable voltage to one or more first target bit lines and apply a first program voltage to a gate electrode of each of the string select transistors SSTG1 of the first group. In response to a first program voltage being applied to a gate electrode of one or more first target string select transistors and a program allowable voltage being applied to one or more first target bit lines, a first program operation, in which one or more first target string select transistors are programmed, may be performed (S1040).

When a voltage higher than a threshold voltage (e.g., 1.7 V) is applied to a specific bit line among a plurality of bit lines BL1 to BL2k, and a first program voltage is applied to a gate electrode of a specific string select transistor connected to a specific bit line, the specific string select transistor may be program-inhibited. In contrast, a particular string select transistor may be programmed when a voltage below the threshold voltage is applied to a particular bit line, and a first program voltage is applied to the gate electrode of the particular string select transistor. In one example, the first voltage (e.g., 1.6 V) of step S1010 may be below the threshold voltage, and the second voltage (e.g., 2.4 V) of step S1020 and the third voltage (e.g., 2.3 V) of step S1030 may be equal to or greater than the threshold voltage. Accordingly, even if the first program voltage is applied to the gate electrode of each of the string select transistors SSTG1 of the first group, only one or more first target string select transistors may be selectively programmed.

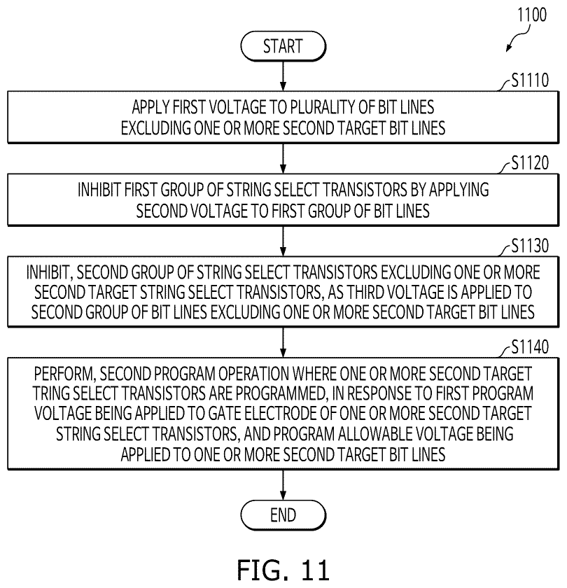

FIG. 11 is a diagram illustrating an example of an operating method 1100 of a non-volatile memory device. The method 1100 illustrated in FIG. 11 may be performed by a control logic circuit (e.g., 320 of FIG. 4) and a page buffer circuit (e.g., 360 of FIG. 4) of a non-volatile memory device.

Referring to FIGS. 9 and 11, the control logic circuit may apply a first voltage to a plurality of bit lines BL1 to BL2k excluding one or more second target bit lines by controlling the page buffer circuit (S1110). For example, the control logic circuit may apply a first voltage to a second group of bit lines BLG2 excluding one or more of the second target bit lines, and to a second group of bit lines BLG1. The first voltage may be the same voltage as the first voltage of step S1010 of FIG. 10. The first voltage may be an internal power voltage of the page buffer circuit.

The one or more second target bit lines of step S1110 may be bit lines connected to one or more second target string select transistors, and the one or more second target string select transistors may be string select transistors to be programmed by a first program voltage in a second program operation among incremental step pulse program (ISPP) operations including a plurality of program operations. The one or more second target string select transistors may be any string select transistor included in the second group of string select transistors SSTG2. The first program voltage may be the same voltage as the first program voltage of step S1040 of FIG. 10.

The control logic circuit may inhibit the string select transistor SSTG1 of the first group by applying a second voltage to the bit line BLG1 of the first group by controlling the page buffer circuit S1120. For example, the control logic circuit may shut off the first voltage applied to the first group of bit lines BLG1 at step S1110 by controlling the page buffer circuit, and then apply the second voltage. Shutting off of the first voltage and applying the second voltage to the bit lines BLG1 of the first group may be performed substantially simultaneously. The second voltage may be the same voltage as the second voltage of step S1020 of FIG. 10.

Because the string select transistors SSTG1 of the first group are inhibited at step S1120, even if the first program voltage is applied to the gate electrode of the string select transistor SSTG1 of the first group, the string select transistor SSTG1 of the first group may be program-prohibited.

At step S1120, a third voltage is applied to the bit lines BLG2 of the second group, excluding one or more second target bit lines, by the second voltage applied to the bit lines BLG1 of the first group, so that the string select transistors SSTG2 of the second group, excluding one or more second target string select transistors, may be inhibited (S1130). For example, because each of the bit lines BLG2 of the second group is coupled to each of the bit lines BLG1 of the first group, even if the control logic circuit does not apply a separate voltage by controlling the page buffer circuit, a third voltage may be applied to the bit lines BLG2 of the second group, excluding one or more of the second target bit lines. At this time, the third voltage may be higher than the first voltage of step S1110 and lower than the second voltage of step S1110. The implementation is not limited to this example, and the same voltage is not necessarily applied to each of the bit lines BLG2 of the second group excluding one or more of the second target bit lines, and third voltages of different magnitudes may be applied to each of the bit lines BLG2 of the second group excluding one or more of the second target bit lines depending on various factors such as interference.

Because the second group of string select transistors SSTG2 excluding one or more of the second target string select transistors are inhibited, even if the first program voltage is applied to the gate electrodes of the second group of string select transistors SSTG2 excluding one or more of the second target string select transistors, the second group of string select transistors SSTG2 excluding one or more of the second target string select transistors may be program-prohibited.

The control logic circuit may apply a program allowable voltage to one or more second target bit lines, and apply a first program voltage to a gate electrode of each of string select transistors SSTG2 of the second group. In response to a first program voltage being applied to a gate electrode of one or more second target string select transistors, and a program allowable voltage being applied to one or more second target bit lines, a second program operation, in which one or more second target string select transistors are programmed, may be performed (S1140).

In one example, the first voltage (e.g., 1.6 V) of step S1110 may be below the threshold voltage described above with reference to FIG. 10, and the second voltage (e.g., 2.4 V) of step S1120 and the third voltage (e.g., 2.3 V) of step S1030 may be equal to or greater than the threshold voltage. Accordingly, even if the second program voltage is applied to the gate electrode of each of the string select transistors SSTG2 of the second group, only one or more second target string select transistors may be selectively programmed.

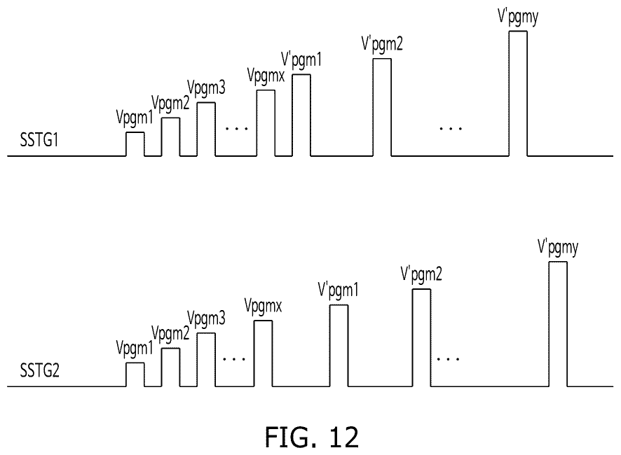

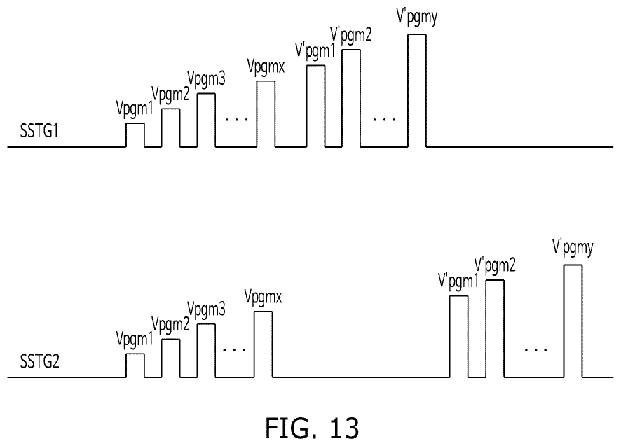

FIGS. 12 and 13 are example diagrams showing a plurality of program voltages applied to a string select transistor. A plurality of program voltages may be applied to the gate electrodes of the string select transistors by the Incremental step pulse program (ISPP) method.

A control logic circuit (e.g., 320 in FIG. 4) may perform x program operations (where x is a natural number greater than or equal to 1). In the x program operations, the program voltages Vpgm1 to Vpgmx, which are input to the gate voltage of the string select transistor, may sequentially increase by an arbitrary value. In x program operations, programs for any string select transistor included in the string select transistors SSTG1 of the first group and any string select transistor included in the string select transistors SSTG2 of the second group may be performed together.

The control logic circuit may, in each of the x program operations, apply a first voltage (e.g., the first voltage of FIGS. 10 and 11) to a bit line connected to a specific string select transistor (e.g., a string select transistor other than a string select transistor to be programmed) to thereby inhibit the string select transistor. A program allowable voltage (e.g., 0 V or ground voltage) may be applied to a bit line where the first voltage is not applied. The control logic circuit may program string select transistors connected to the bit lines where the first voltage is not applied, by applying a program voltage (e.g., Vpgm1) to the gate electrode of each of the string select transistors SSTG1 of the first group and the string select transistors SSTG2 of the second group.

After x program operations using x program voltages Vpgm1 to Vpgmx are performed, y program operations for the string select transistors SSTG1 of the first group and y program operations for the string select transistors SSTG2 of the second group may be performed using y program voltages V′pgm1 to V′pgmy. That is, unlike the above-described x program operations, the program operation for the string select transistors SSTG1 of the first group and the program operation for the string select transistors SSTG2 of the second group may be performed alternately and/or separately.

In one example, each of the y program operations for the string select transistors SSTG1 of the first group may be performed by the process described above with reference to FIG. 10. Additionally, each of the y program operations for the string select transistors SSTG2 of the second group may be performed by the process described above with reference to FIG. 11.

In one implementation, in response to a particular condition being satisfied, a program operation using y program voltages V′pgm1 to V′pgmy may be initiated. For example, the control logic circuit may initiate 2y program operations using y program voltages V′pgm1 to V′pgmy in response to determining that x program operations correspond to a predetermined threshold number of program operations or that the x-th program voltage Vpgmx used in the x-th program operation is equal to or greater than the threshold voltage. For example, the threshold voltage may be a voltage at which a string select transistor is not programmed even if a gate electrode of the string select transistor connected to the bit line to which the first voltage is applied is applied when the first voltage is applied to the bit line. By initiating 2y program operations in response to certain conditions being satisfied, the increase in overall program time may be minimized.

Referring to FIG. 12, among 2y program operations using y program voltages V′pgm1 to V′pgmy, y program operations for the string select transistors SSTG1 of the first group and y program operations for the string select transistors SSTG2 of the second group may be performed alternately. For example, the control logic circuit may perform a program operation for any string select transistor included in the string select transistors SSTG1 of the first group by using the program voltage V′pgm1, may perform a program operation for any string select transistor included in the string select transistors SSTG2 of the second group by using the same program voltage V′pgm1, and may repeatedly perform the program operation by increasing the program voltage until the program operation for the string select transistors SSTG1 of the first group and the string select transistors SSTG2 of the second group is completed.

Referring to FIG. 13, after y program operations for the string select transistors SSTG1 of the first group are completed among 2y program operations using y program voltages V′pgm1 to V′pgmy, y program operations for the string select transistors SSTG2 of the second group may be performed.

Unlike what is shown in FIGS. 12 and 13, the 2y program operations may be performed in any order. In one example, two program operations are performed on the string select transistors SSTG1 of the first group, two program operations are performed on the string select transistors SSTG2 of the second group, and by repeating these operations, 2y program operations may be performed.

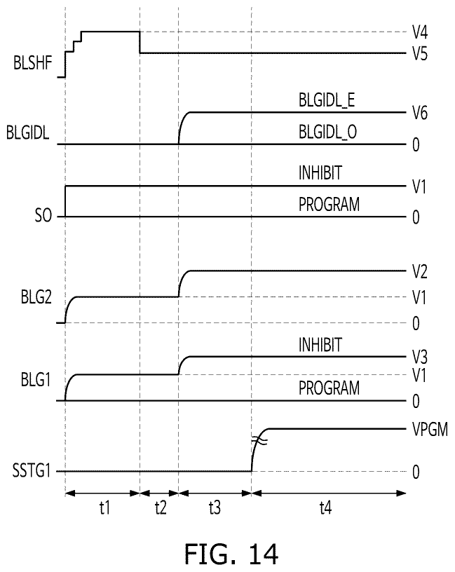

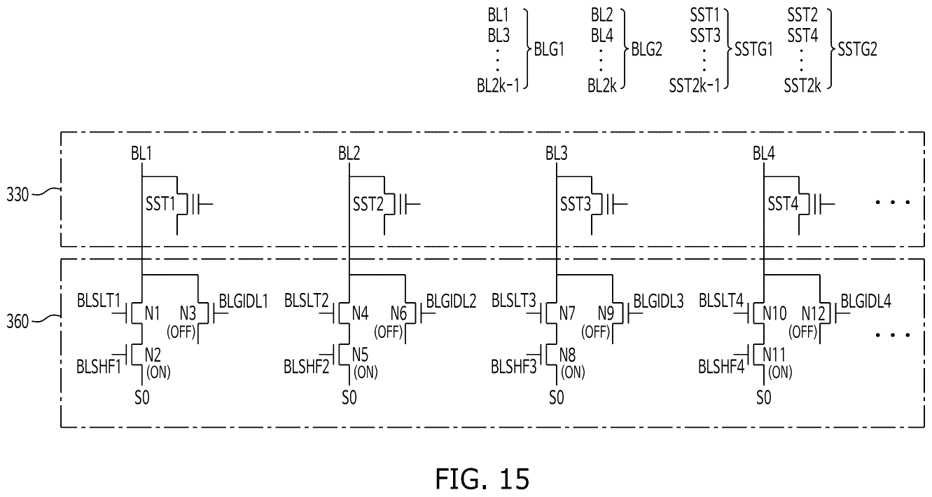

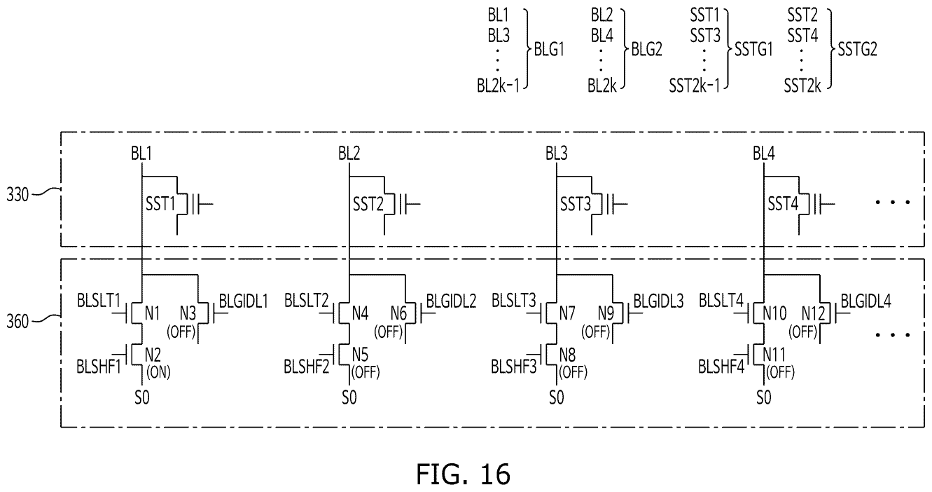

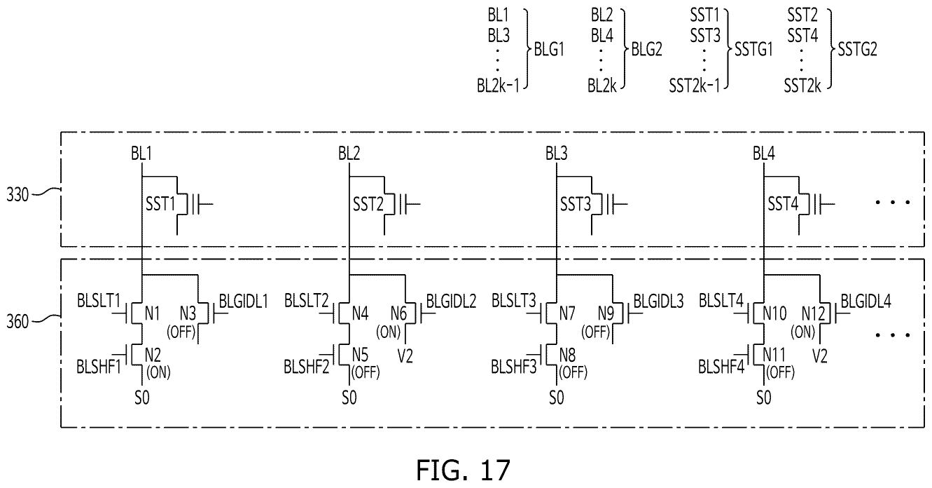

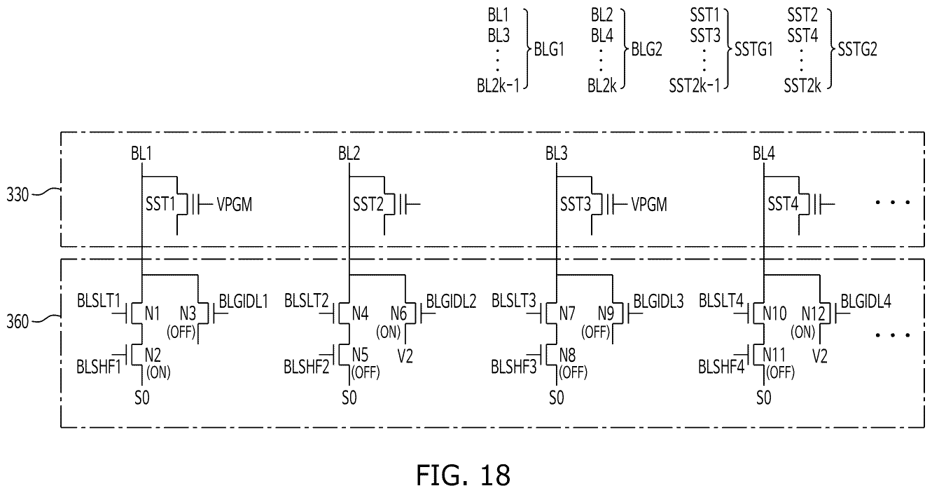

FIG. 14 is an example timing diagram for explaining the program operation of FIG. 10, FIG. 15 is an example diagram for explaining the operation of the page buffer circuit at a first time t1 of FIG. 14, FIG. 16 is an example diagram for explaining the operation of the page buffer circuit at a second time t2 of FIG. 14, FIG. 17 is an example diagram for explaining the operation of the page buffer circuit at a third time t3 of FIG. 14, and FIG. 18 is an example diagram for explaining the operation of the page buffer circuit at a fourth time t4 of FIG. 14. In FIGS. 15 to 18, the illustration and description of configurations other than the configuration of the non-volatile memory device necessary to explain the program operation of FIG. 10 may be omitted.

The program operation described with reference to FIGS. 15 to 18 may be a program operation in which any one of the y program voltages V′pgm1 to V′pgmy of FIGS. 12 and 13 is applied to the gate electrode of the string select transistors SSTG1 of the first group.

The operation of the page buffer circuit 360 of FIGS. 15 to 18 may be performed based on a control signal of a control logic circuit (e.g., 320 of FIG. 4). For example, the control logic circuit may control the turn-on and turn-off of the bit line select transistors N1, N4, N7 and N10, the bit line shut-off transistors N2, N5, N8 and N11, and the precharge transistors N3, N6, N9 and N12 by transmitting a control signal to the page buffer circuit 360 (or each transistor). The page buffer circuit may apply a first voltage V1 or a second voltage V2 to each of a plurality of bit lines BL1 to BL2k based on a control signal of a control logic circuit. In FIGS. 15 to 18, it is assumed that bit line select transistors N1, N4, N7 and N10 are turned on by bit line select signals BLSLT1, BLSLT2, BLSLT3 and BLSLT4.

Referring to FIGS. 14 and 15, during a first time t1, the bit line shut-off signals BLSHF1, BLSHF2, BLSHF3 and BLSHF4 of the bit line shut-off transistors N2, N5, N8 and N11 are applied with a fourth voltage V4 (e.g., 3 V), thereby turning on the bit line shut-off transistors N2, N5, N8 and N11.

By turning on the bit line shut-off transistors N2, N5, N8 and N11, the voltage applied to the node SO may be applied to the bit lines of the first group BLG1 and the bit lines of the second group BLG2. A first voltage V1 may be applied from a node SO to a bit line BLG1 of the first group whose program is to be inhibited, and to a bit line BLG2 of the second group. The first voltage V1 may be an internal power voltage of the page buffer circuit 360. For example, the page buffer circuit may apply a first voltage V1 to a bit line BLG1 to be program-inhibited among the first group of bit lines, and the second group of bit lines BLG2. The first voltage V1 may not be applied from the node SO to the bit line to be programmed among the bit lines BLG1 of the first group. A program allowable voltage (e.g., 0 V or ground voltage) may be applied to a first target bit line to be programmed (or a first target string select transistor to be programmed) among the bit lines BLG1 of the first group. For example, the page buffer circuit may apply a program allowable voltage to a first target bit line to be programmed (or a first target string select transistor to be programmed) among the bit lines BLG1 of the first group.

For example, the control logic circuit may apply a program allowable voltage to a first bit line BL1, which is a first target bit line, and apply a first voltage V1 to a second bit line BL2, a third bit line BL3, and a fourth bit line BL4 by turning on bit line shut-off transistors N2, N5, N8 and N11 for a first time t1.

Referring to FIG. 14 and FIG. 16, the control logic circuit may block a first voltage V1 applied to bit lines other than a first target bit line among a plurality of bit lines BL1 to BL2k for a second time t2.

For example, the control logic circuit may turn off the second bit line shut-off transistor N5, the third bit line shut-off transistor N8, and the fourth bit line shut-off transistor N11 by changing the bit line shut-off signals BLSHF2, BLSHF3 and BLSHF4 to a fifth voltage V5 (e.g., 1.5 V) and applying the fifth voltage V5 for a second time t2, thereby blocking the first voltage V1 from the second bit line BL2, the third bit line BL3, and the fourth bit line BL4.

In one implementation, the second time t2 may be a time which is close to zero or substantially zero.

Referring to FIG. 14 and FIG. 17, a second voltage V2 (e.g., 2.4 V) may be applied to the bit lines BLG2 of the second group for a third time t3. For example, the control logic circuit may apply a sixth voltage V6 (e.g., 20 V), which turns on the precharge transistors N6 and N12, to the gate electrodes of the precharge transistors N6 and N12 connected to the bit line BLG2 of the second group, as precharge signals BLGIDL2 and BLGIDL4. The control logic circuit may not apply the sixth voltage V6 as precharge signals BLGIDL1 and BLGIDL3 to the gate electrodes of the precharge transistors N3 and N9 connected to the bit lines BLG1 of the first group. The control logic circuit may apply a turn-off voltage (e.g., 0 V or ground voltage) to the gate electrodes of the precharge transistors N3 and N9 connected to the bit lines BLG1 of the first group.

As the precharge transistors N6 and N12 connected to the bit line BLG2 of the second group are turned on, a second voltage V2 is applied to the bit lines BLG2 of the second group during a third time t3, and the string select transistors SSTG2 of the second group may be inhibited. For example, as the second precharge transistor N6 and the fourth precharge transistor N12 are turned on, the second voltage V2 is applied to the second bit line BL2 and the fourth bit line BL4 during a third time t3, and the second string select transistor SST2 and the fourth string select transistor SST4 may be inhibited.

As a third voltage V3 is applied to the bit lines BLG1 of the first group, excluding one or more first target bit lines, by a second voltage V2 applied to the bit lines BLG2 of the second group, the string select transistors SSTG1 of the first group, excluding one or more first target string select transistors, may be inhibited. For example, the third string select transistor SST3 may be inhibited, excluding the first string select transistor SST1, which is the first target string select transistor.

Referring to FIG. 14 and FIG. 18, a program voltage VPGM may be applied to the gate electrode of the string select transistor SSTG1 of the first group during the fourth time t4. For example, the program voltage VPGM may be any one of the y program voltages V′pgm1 to V′pgmy shown in FIGS. 12 and 13.

Because the string select transistors SSTG1 of the first group, excluding the first target string select transistor, are inhibited during the third time t3 and the fourth time t4, even if the program voltage VPGM is applied to the gate electrode of the string select transistors SSTG1 of the first group, only the first target string select transistor may be programmed. For example, in response to a program voltage VPGM being applied to the gate electrodes of each of the first string select transistor SST1 and the third string select transistor SST3 and a program allowable voltage (e.g., 0 V) being applied to the first bit line BL1, the first string select transistor SST1 may be programmed. In contrast, in response to a program voltage VPGM being applied to the gate electrode of the third string select transistor SST3 and a third voltage V3 being applied to the third bit line BL3, the third string select transistor SST3 may be inhibited from being programmed.

In FIG. 14 and FIG. 18, it is illustrated that the program voltage VPGM is applied to the gate electrode of the string select transistor SSTG1 of the first group for the fourth time t4, but the implementation is not limited to this example. Additionally, a program voltage VPGM may be applied to the gate electrode of the string select transistor SSTG2 of the second group for the fourth time t4, and the program of the string select transistor SSTG2 of the second group may be inhibited as the string select transistor SSTG2 of the second group is inhibited by the second voltage V2.

The phenomenon of the string select transistor being over-programmed may be prevented by applying a voltage (e.g., V2 or V3) higher than the internal power voltage of the page buffer circuit to a bit line connected to a string select transistor that is not to be programmed, through the implementation described above with reference to FIGS. 14 to 18.

The time required for a program operation may be shortened by performing a two step process of applying a voltage (e.g., V1) to a bit line connected to a string select transistor not to be programmed and then applying a higher voltage again, through the implementation described with reference to FIGS. 14 to 18. In addition, the leakage characteristic of the string select transistor may be improved, and the setup time until the corresponding voltage is applied to the bit lines may be shortened by reducing the voltage difference between adjacent program inhibit bit lines (e.g., any bit line among the bit lines BLG1 of the first group and any bit line among the bit lines BLG2 of the second group adjacent thereto), compared to the case where a specific voltage (e.g., V2) required to inhibit the string select transistor is directly applied.

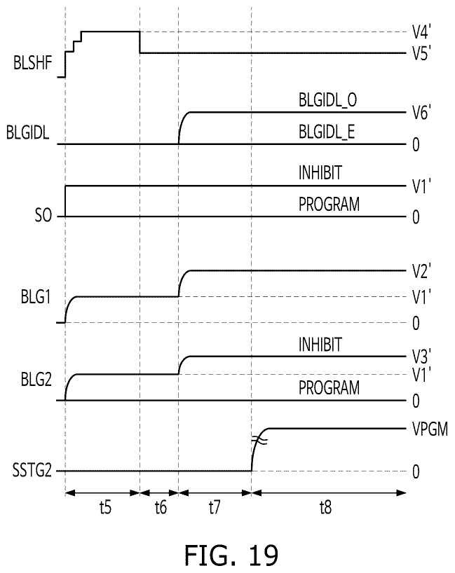

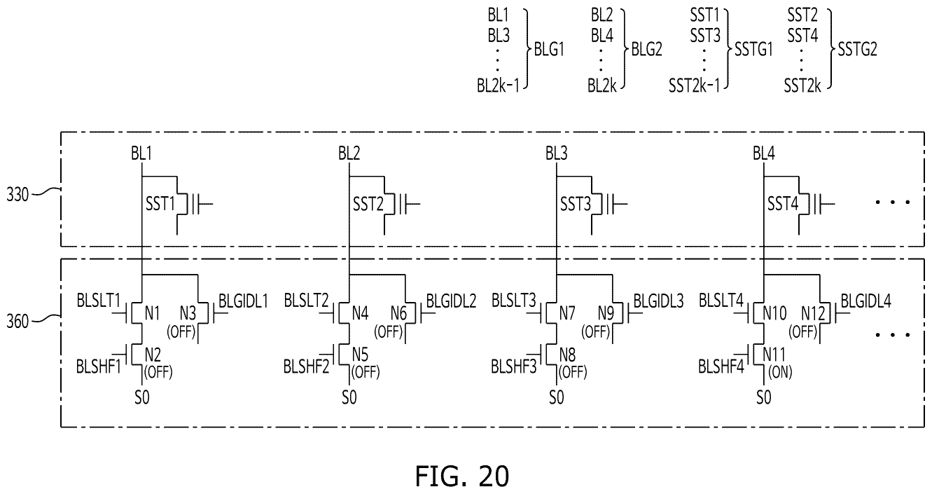

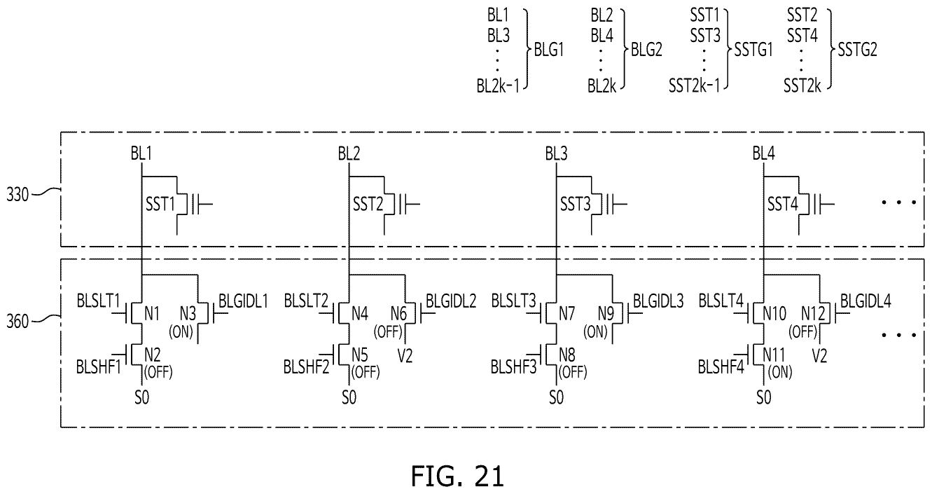

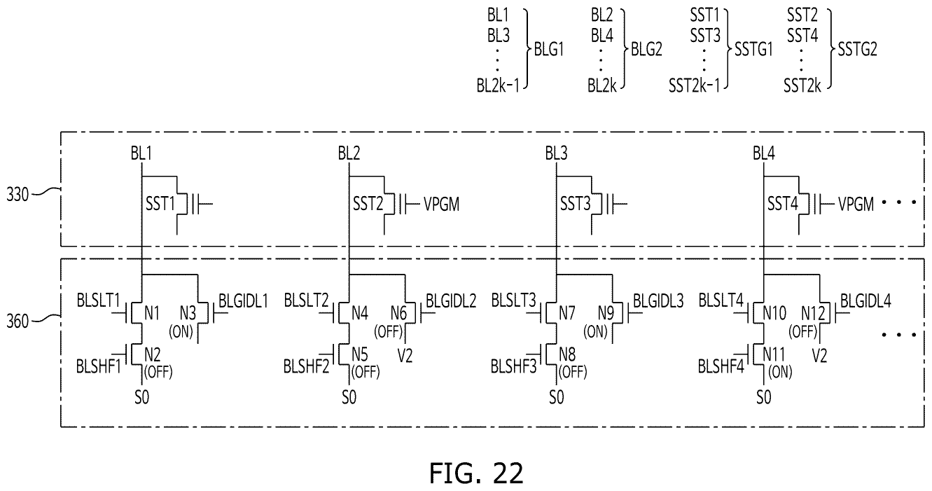

FIG. 19 is an example timing diagram for explaining the program operation of FIG. 11, FIG. 20 is an example diagram for explaining the operation of the page buffer circuit at the 6th time t6 of FIG. 19, FIG. 21 is an example diagram for explaining the operation of the page buffer circuit at the 7th time t7 of FIG. 19, and FIG. 22 is an example diagram for explaining the operation of the page buffer circuit at the 8th time t8 of FIG. 19. In FIGS. 20 to 22, the illustration and description of configurations other than the configuration of the non-volatile memory device necessary to explain the program operation of FIG. 11 may be omitted.

The program operation described with reference to FIGS. 20 to 22 may be a program operation in which the program voltage VPGM of FIG. 19 is applied to the gate electrode of the string select transistor SSGT2 of the second group. The program voltage VPGM of FIG. 19 may be the same voltage as the program voltage VPGM of FIG. 14.

The operation of the page buffer circuit 360 of FIGS. 20 to 22 may be performed based on a control signal of a control logic circuit (e.g., 320 of FIG. 4). For example, the control logic circuit may control the turn-on and turn-off of the bit line select transistors N1, N4, N7 and N10, the bit line shut-off transistors N2, N5, N8 and N11, and the precharge transistors N3, N6, N9 and N12 by transmitting a control signal to the page buffer circuit 360 (or each transistor). The page buffer circuit may apply a first voltage V1′ or a second voltage V2′ to each of a plurality of bit lines BL1 to BL2k based on a control signal of the control logic circuit. In FIGS. 20 to 22, it is assumed that bit line select transistors N1, N4, N7 and N10 are turned on by bit line select signals BLSLT1, BLSLT2, BLSLT3 and BLSLT4.

The operation of the page buffer circuit 360 illustrated and described with reference to FIG. 15 may correspond to the operation of the page buffer circuit 360 for the fifth time t5 of FIG. 19.

Referring to FIG. 15 and FIG. 19, the bit line shut-off signals BLSHF1, BLSHF2, BLSHF3 and BLSHF4 of the bit line shut-off transistors N2, N5, N8 and N11 are applied with a fourth voltage V4′ (e.g., the same voltage as the fourth voltage V4 of FIG. 14) for the fifth time t5, thereby turning on the bit line shut-off transistors N2, N5, N8 and N11.

By turning on the bit line shut-off transistors N2, N5, N8 and N11, the voltage applied to the node SO may be applied to the bit lines of the second group BLG2 and the bit lines of the first group BLG1. A first voltage V1′ (e.g., the same voltage as the first voltage V1 of FIG. 14) may be applied from the node SO to bit lines BLG2, which will be program-inhibited, of the second group, and to bit lines BLG1 of the first group. For example, the page buffer circuit may apply a first voltage V1′ to bit lines BLG2, which will be program-inhibited, of the second group and to bit lines BLG1 of the first group. The first voltage V1′ may not be applied from the node SO to bit lines, which will be programmed, among the bit lines BLG2 of the second group. A program allowable voltage (e.g., 0 V or ground voltage) may be applied to a second target bit line to be programmed (or a second target string select transistor to be programmed) among the bit lines of the second group BLG2. For example, the page buffer circuit may apply a program allowable voltage to a second target bit line to be programmed (or a second target string select transistor to be programmed) among the bit lines of the second group BLG2.

For example, the control logic circuit may apply a program allowable voltage to a fourth bit line BL4, which is a second target bit line, and apply a first voltage V1′ to the first bit line BL1, the second bit line BL2, and the third bit line BL3 by turning on the bit line shut-off transistors N2, N5, N8 and N11 for a fifth time t5.

Referring to FIGS. 19 and 20, the control logic circuit may block the first voltage V1′ applied to bit lines other than the second target bit line among the plurality of bit lines BL1 to BL2k for a sixth time t6.

For example, the control logic circuit may turn off the first bit line shut-off transistor N2, the second bit line shut-off transistor N5, and the third bit line shut-off transistor N8 by changing the bit line shut-off signals BLSHF2, BLSHF3 and BLSHF4 to a fifth voltage V5′ (e.g., the same voltage as the fifth voltage V5 of FIG. 14), thereby blocking the first voltage V1′ from the first bit line BL1, the second bit line BL2, and the third bit line BL3.

In one implementation, the sixth time t6 may be a time that is close to zero or substantially zero.

Referring to FIG. 19 and FIG. 21, a second voltage V2′ (e.g., the same voltage as the second voltage V2 of FIG. 14) may be applied to the bit lines BLG1 of the first group for a seventh time t7. For example, the control logic circuit may apply a sixth voltage V6′ (e.g., the same voltage as the sixth voltage V6 of FIG. 14), which turns on the precharge transistors N3 and N9, to the gate electrodes of the precharge transistors N3 and N9 connected to the bit line BLG1 of the first group, as a precharge signals BLGIDL1 and BLGIDL3. The control logic circuit may not apply the sixth voltage V6′ as the precharge signals BLGIDL2 and BLGIDL4, to the gate electrodes of the precharge transistors N6 and N12 connected to the bit line BLG2 of the second group. The control logic circuit may apply a turn-off voltage (e.g., 0 V or ground voltage) to the gate electrodes of the precharge transistors N6 and N12 connected to the bit lines BLG2 of the second group.

As the precharge transistors N3 and N9 connected to the bit lines BLG1 of the first group are turned on, the second voltage V2′ may be applied to the bit lines BLG1 of the first group for a seventh time t7, and the string select transistor SSGT1 of the first group may be inhibited. For example, as the first precharge transistor N3 and the third precharge transistor N9 are turned on, the second voltage V2′ may be applied to the first bit line BL1 and the third bit line BL3 for a seventh time t7, and the first string select transistor SST1 and the third string select transistor SST3 may be inhibited.

The string select transistors SSGT2 of the second group, excluding one or more second target string select transistors, may be inhibited as a third voltage V3′ (e.g., the same voltage as the third voltage V3 of FIG. 14) is applied to the bit lines BLG2 of the second group, excluding one or more second target bit lines, by a second voltage V2′ applied to the bit lines BLG1 of the first group. For example, the second string select transistor SST2 may be inhibited, except for the fourth string select transistor SST4, which is the second target string select transistor.

Referring to FIG. 19 and FIG. 22, a program voltage VPGM may be applied to the gate electrode of the string select transistor SSGT2 of the second group for the eighth time t8.

Because the string select transistors SSGT2 of the second group except for the second target string select transistor are inhibited at the seventh time t7 and the eighth time t8, even if the program voltage VPGM is applied to the gate electrode of the string select transistors SSGT2 of the second group, only the second target string select transistor may be programmed. For example, in response to a program voltage VPGM being applied to the gate electrode of each of the second string select transistors SST2 and the fourth string select transistors SST4 and a program allowable voltage (e.g., 0 V) being applied to the fourth bit line BL4, the fourth string select transistor SST4 may be programmed. In contrast, in response to a program voltage VPGM being applied to the gate electrode of the second string select transistor SST2 and a third voltage V3′ being applied to the second bit line BL2, the second string select transistor SST2 may be program-inhibited(e.g., prevented from being programmed).

In FIGS. 19 and 22, it is illustrated that the program voltage VPGM is applied to the gate electrodes of the string select transistors SSTG2 of the second group for the 8th time t8, but the implementations are not limited to these examples. Additionally, a program voltage VPGM may be applied to the gate electrode of the string select transistor SSTG1 of the first group for the eighth time t8, and the program of the string select transistor SSTG1 of the first group may be inhibited as the string select transistor SSTG1 of the first group is inhibited by the second voltage V2′.

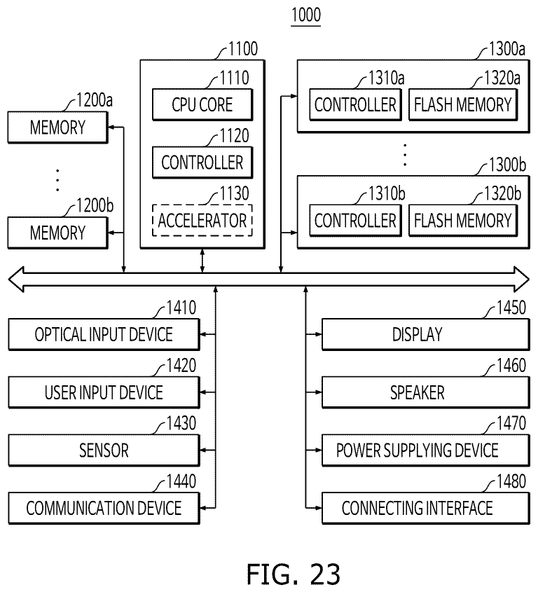

FIG. 23 is an example block diagram illustrating a system including a non-volatile

### Memory Device.

Referring to FIG. 23, a system 1000 may be a mobile system, such as a mobile phone, a smart phone, a tablet personal computer, a wearable device, a healthcare device, or an Internet of Things (IoT) device. However, the system 1000 of FIG. 23 is not necessarily limited to a mobile system, and may be a personal computer, a laptop computer, a server, a media player, or an automotive device such as a navigation device.

Referring to FIG. 23, the system 1000 may include a main processor 1100, memories 1200a and 1200b, and storage devices 1300a and 1300b, and may additionally include one or more of an image capturing device 1410, a user input device 1420, a sensor 1430, a communication device 1440, a display 1450, a speaker 1460, a power supplying device 1470, and a connecting interface 1480. The storage device 1300a or 1300b may be a non-volatile memory device (e.g., 300 of FIG. 2 or 300 of FIG. 4) according to some implementations.

The main processor 1100 may control the overall operation of the system 1000, more specifically, the operation of other components that make up the system 1000. Such a main processor 1100 may be implemented as a general-purpose processor, a dedicated processor, or an application processor.

The main processor 1100 may include one or more CPU cores 1110 and may further include a controller 1120 for controlling memories 1200a and 1200b and/or storage devices 1300a and 1300b. According to an implementation, the main processor 1100 may further include an accelerator block 1130, which is a dedicated circuit for high-speed data operations such as artificial intelligence (AI) data operations. Such an accelerator block 1130 may include a Graphics Processing Unit (GPU), a Neural Processing Unit (NPU), and/or a Data Processing Unit (DPU), and may be implemented as a separate chip that is physically independent from other components of the main processor 1100.

The memory 1200a or 1200b may be used as a main memory device of the system 1000 and may include a volatile memory such as SRAM and/or DRAM, but may also include a non-volatile memory such as flash memory, PRAM and/or RRAM. The memory 1200a or 1200b may also be implemented within the same package as the main processor 1100.

The storage device 1300a or 1300b may function as a non-volatile storage device that stores data regardless of whether power is supplied, and may have a relatively large storage capacity compared to the memory 1200a or 1200b. The storage device 1300a or 1300b may include a storage controller 1310a or 1310b and a non-volatile memory NVM storage 1320a or 1320b that stores data under the control of the storage controller 1310a or 1310b. Then non-volatile storage 1320a or 1320b may include V-NAND flash memory in a 2-dimensional structure or a 3-dimensional structure, but may also include other types of non-volatile memory such as PRAM and/or RRAM.

The storage device 1300a or 1300b may be included in the system 1000 in a state that is physically separated from the main processor 1100, or may be implemented within the same package as the main processor 1100. Additionally, because the storage device 1300a or 1300b has a form such as a memory card, the storage device 1300a or 1300b may be detachably coupled with other components of the system 1000 through an interface such as a connection interface 1480 to be described later. The storage device 1300a or 1300b may be a device to which standard specifications such as UFS universal flash storage apply, but the implementation is not limited to this example.

The image capturing device 1410 may capture still images or moving images and may be a camera, a camcorder, and/or a webcam.

The user input device 1420 may receive various types of data which are input from a user of the system 1000, and may be a touch pad, a keypad, a keyboard, a mouse, and/or a microphone.

The sensor 1430 may detect various types of physical quantities that may be obtained from outside the system 1000 and convert the detected physical quantities into electrical signals. Such a sensor 1430 may be a temperature sensor, a pressure sensor, an illuminance sensor, a position sensor, an acceleration sensor, a biosensor, and/or a gyroscope.

A communication device 1440 may transmit and receive signals between other devices outside the system 1000 according to various communication protocols. Such a communication device 1440 may be implemented to include an antenna, a transceiver, and/or a modem.

A display 1450 and a speaker 1460 may function as output devices that output visual information and auditory information, respectively, to the user of the system 1000.

A power supply device 1470 may appropriately convert power supplied from a battery, which is built in the system 1000, and/or an external power source, and supply the converted power to each component of the system 1000.

The connection interface 1480 may provide a connection between the system 1000 and an external device that is connected to the system 1000 and may exchange data with the system 1000. The connection interface 1480 may be implemented in various interface methods, such as an advanced technology attachment (ATA), small computer small interface (SCSI), serial attached SCSI (SAS), peripheral component interconnection (PCI), pCI express (PCIe), non-volatile memory express (NVMe), IEEE 1394, universal serial bus (USB), secure digital (SD), multi-media card (MMC), embedded multi-media card (eMMC), universal flash storage (UFS), embedded universal flash storage (eUFS), and compact flash (CF) card interface.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The present disclosure is not limited to the above-described implementations and the attached drawings, and various substitutions, modifications, and changes may be made by those skilled in the art without departing from the technical spirit of the present disclosure, and this will also fall within the scope of the present disclosure. For example, one or more steps of a process described with reference to a flowchart illustrated in some drawings may be omitted, the order of each step may be changed, one or more steps may be performed with temporal overlap, or one or more steps may be performed repeatedly a plurality of times.

1. A non-volatile memory device comprising:
a control logic circuit configured to generate a program signal;
a voltage generator configured to
receive the program signal from the control logic circuit, and
generate a first program voltage based on the received program signal;
a plurality of string select transistors comprising a first string select transistor, a second string select transistor, and a third string select transistor, the first string select transistor being configured to be programmed based on the first program voltage;
a plurality of bit lines comprising a first bit line, a second bit line, and a third bit line, the first bit line being connected with the first string select transistor, the second bit line being connected with the second string select transistor, and the third bit line being connected with the third string select transistor and adjacent to the second bit line; and
a page buffer circuit connected with the plurality of bit lines and configured to apply a first voltage or a second voltage to each bit line of the plurality of bit lines, the second voltage being greater than the first voltage,
wherein the control logic circuit is configured to control the page buffer circuit to:
apply the first voltage to the second bit line and the third bit line; and
apply the second voltage to the second bit line to (i) inhibit the second string select transistor and (ii) apply a third voltage to the third bit line to cause the third string select transistor to be inhibited.

2. The non-volatile memory device of claim 1, wherein the first voltage is an internal power voltage of the page buffer circuit.

3. The non-volatile memory device of claim 1, wherein the third voltage is higher than the first voltage and lower than the second voltage.

4. The non-volatile memory device of claim 1, wherein the third string select transistor is configured to be program-inhibited based on a voltage equal to or greater than a threshold voltage being applied to the third bit line and the first program voltage being applied to a gate electrode of the third string select transistor,
wherein the third string select transistor is configured to be programmed based on a voltage lower than the threshold voltage being applied to the third bit line and the first program voltage being applied to the gate electrode of the third string select transistor, and
wherein the third voltage is equal to or greater than the threshold voltage.

5. The non-volatile memory device of claim 4, wherein the first voltage is less than the threshold voltage.

6. The non-volatile memory device of claim 1, wherein the control logic circuit is configured to:
apply a program allowable voltage to the first bit line; and
apply the first program voltage to a first gate electrode of the first string select transistor and a third gate electrode of the third string select transistor among the plurality of string select transistors,
wherein the first string select transistor is configured to be programmed based on the first program voltage being applied to the first gate electrode of the first string select transistor and the program allowable voltage being applied to the first bit line, and
wherein the third string select transistor is configured to be program-inhibited based on the first program voltage being applied to the third gate electrode of the third string select transistor and the third voltage being applied to the third bit line.

7. The non-volatile memory device of claim 1, wherein the control logic circuit is configured to perform an incremental step pulse program (ISPP) operation for the plurality of string select transistors, the ISPP operation comprising a plurality of program operations, and
wherein the plurality of program operations comprise a first program operation, the first program operation being configured to program the first string select transistor based on applying the first program voltage to a first gate electrode of the first string select transistor and a third gate electrode of the third string select transistor among the plurality of string select transistors.

8. The non-volatile memory device of claim 7, wherein the control logic circuit is configured to, based on determining that the first program operation corresponds to a program operation to be performed after a threshold number of program operations among the plurality of program operations, control the page buffer circuit to apply the first voltage to the second bit line and the third bit line and to apply the second voltage to the second bit line.

9. The non-volatile memory device of claim 8, wherein the plurality of program operations comprise a second program operation, the second program operation being included in the threshold number of program operations, and
wherein the control logic circuit is configured to:
apply the first voltage to a bit line connected with a second plurality of string select transistors among the plurality of string select transistors excluding one or more string select transistors to be programmed by the second program operation; and
perform the second program operation to program the one or more string select transistors based on applying a second program voltage to a gate electrode of each string select transistor of the plurality of string select transistors.

10. The non-volatile memory device of claim 7, wherein the control logic circuit is configured to, based on determining that the first program voltage to be applied to a gate electrode of each string select transistor of the plurality of string select transistors is equal to or greater than a threshold voltage, control the page buffer circuit to apply the first voltage to the second bit line and the third bit line and to apply the second voltage to the second bit line.

11. The non-volatile memory device of claim 1, wherein the page buffer circuit comprises:
a first shut-off circuit comprising a first shut-off transistor connected with the first bit line and configured to apply or block the first voltage to the first bit line;
a second shut-off circuit comprising a second shut-off transistor connected with the second bit line and configured to apply or block the first voltage to the second bit line;
a third shut-off circuit comprising a third shut-off transistor connected with the third bit line and configured to apply or block the first voltage to the third bit line;
a first precharge circuit comprising a first precharge transistor connected with the first bit line and configured to apply or block the second voltage to the first bit line;
a second precharge circuit comprising a second precharge transistor connected with the second bit line and configured to apply or block the second voltage to the second bit line; and
a third precharge circuit comprising a third precharge transistor connected with the third bit line and configured to apply or block the second voltage to the third bit line,
wherein the control logic circuit is configured to, based on transmitting a control signal to the first shut-off transistor, the second shut-off transistor, the third shut-off transistor, the first precharge transistor, the second precharge transistor, and the third precharge transistor, turn on or turn off the first shut-off transistor, the second shut-off transistor, the third shut-off transistor, the first precharge transistor, the second precharge transistor, and the third precharge transistor.

12. The non-volatile memory device of claim 11, wherein the control logic circuit is configured to, based on turning on the second shut-off transistor and the third shut-off transistor, apply the first voltage to the second bit line and the third bit line.

13. The non-volatile memory device of claim 11, wherein the control logic circuit is configured to:
block, based on turning off the second shut-off transistor, the first voltage from the second bit line; and
apply, based on turning on the second precharge transistor, the second voltage to the second bit line.

14. A non-volatile memory device comprising:
a control logic circuit configured to generate a program signal;
a voltage generator configured to
receive the program signal from the control logic circuit, and
generate a first program voltage based on the received program signal;
a plurality of string select transistors comprising a first group of string select transistors and a second group of string select transistors, the first group of string select transistors comprising at least one first target string select transistor to be programmed by the first program voltage;
a plurality of bit lines comprising:
a first group of bit lines connected with the first group of string select transistors and comprising at least one first target bit line connected with the at least one first target string select transistor; and
a second group of bit lines disposed between each bit line of the first group of bit lines and connected with the second group of string select transistors; and
a page buffer circuit connected with the plurality of bit lines and configured to apply a first voltage or a second voltage to each bit line of the plurality of bit lines, the second voltage being greater than the first voltage,
wherein the control logic circuit is configured to:
apply the first voltage to the plurality of bit lines excluding the at least one first target bit line; and
apply the second voltage to the second group of bit lines to (i) inhibit the second group of string select transistors and (ii) apply a third voltage to a first group of bit lines excluding the at least one first target bit line to cause a first group of string select transistors excluding the at least one first target string select transistor to be inhibited.

15. The non-volatile memory device of claim 14, wherein a first plurality of bit lines of the first group are not adjacent to each other,
wherein a second plurality of bit lines of the second group are not adjacent to each other, and
wherein each bit line of the first group of bit lines and each bit line of the second group of bit lines are disposed to intersect each other.

16. The non-volatile memory device of claim 14, wherein the control logic circuit is configured to:
apply a program allowable voltage to the at least one first target bit line; and
apply the first program voltage to a gate electrode of each string select transistor of the first group of string select transistors, and
wherein a first program operation in which the at least one first target string select transistor is programmed is performed based on the first program voltage being applied to the gate electrode of the at least one first target string select transistor and the program allowable voltage being applied to the at least one first target bit line.

17. The non-volatile memory device of claim 16, wherein the second group of string select transistors comprise at least one second target string select transistor to be programmed by the first program voltage,
wherein the second group of bit lines comprise at least one second target bit line connected with the at least one second target string select transistor,
wherein the control logic circuit is configured to:
apply the first voltage to the plurality of bit lines excluding the at least one second target bit line;
apply the second voltage to the first group of bit lines to (i) inhibit the first group of string select transistors and (ii) apply a third voltage to the second group of bit lines excluding the at least one second target bit line to cause the second group of string select transistors excluding the at least one second target string select transistor to be inhibited;
apply the program allowable voltage to the at least one second target bit line; and
apply the first program voltage to the gate electrode of each string select transistor of the second group of string select transistors, and
wherein a second program operation in which the at least one second target string select transistor is programmed is performed based on the first program voltage being applied to the gate electrode of the at least one second target string select transistor and the program allowable voltage being applied to the at least one second target bit line.

18. The non-volatile memory device of claim 16, wherein the control logic circuit is configured to:
perform an incremental step pulse program (ISPP) operation for the plurality of string select transistors, the ISPP operation comprising a plurality of program operations, wherein the plurality of program operations comprise the first program operation;
determine that the first program operation satisfies a predetermined condition associated with the first program operation; and
control, based on determining that the first program operation satisfies the predetermined condition, the page buffer circuit to apply the first voltage to the first group of bit lines and the second group of bit lines excluding the at least one first target bit line, and to apply the second voltage to the second group of bit lines.

19. The non-volatile memory device of claim 18, wherein the predetermined condition corresponds to a first condition that the first program operation is performed after a threshold number of program operations among the plurality of program operations, or the predetermined condition corresponds to a second condition that the first program voltage is equal to or greater than a threshold voltage.

20. A method of operating a non-volatile memory device comprising a control logic circuit, a first string select transistor, a second string select transistor, a third string select transistor, a first bit line connected with the first string select transistor, a second bit line connected with the second string select transistor, a third bit line connected with the third string select transistor and adjacent to the second bit line, and a page buffer circuit, the method comprising:
controlling, by the control logic circuit, the page buffer circuit to apply a first voltage to the second bit line and the third bit line;
controlling, by the control logic circuit, the page buffer circuit to apply a second voltage greater than the first voltage to the second bit line to inhibit the second string select transistor and the third string select transistor; and
programming, by the control logic circuit based on applying a program voltage to a first gate electrode of the first string select transistor and a third gate electrode of the third string select transistor, the first string select transistor.
